(19) United States
(12) Patent Application Publication
(10) Pub. No.: US 2025/0068799 A1
(43) Pub. Date: Feb. 27, 2025

(54) DIGITAL MODEL AND DIGITAL TWIN GENERATION USING GENERATIVE TRANSFORMER NETWORKS AND LARGE LANGUAGE MODELS

(71) Applicant: CHAOS INDUSTRIES, INC., Hermosa Beach, CA (US)

(72) Inventors: Harry Bourne MARR, JR., Manhattan Beach, CA (US); Eugenio CULURCIELLO, Hermosa Beach, CA (US); Ryan RETTING, Torrance, CA (US)

(21) Appl. No.: 18/454,735

(22) Filed: Aug. 23, 2023

(51) Int. Cl. G06F 30/27; G06N 3/0455; G06N 3/0475

(52) U.S. Cl. CPC G06F 30/27; G06N 3/0455; G06N 3/0475

(57) ABSTRACT

Digital model and digital twin generation using generative transformer networks and large language models is described. A digital twin generator is configured to generate a digital twin of a physical system useable for electronic testing with simulated real world conditions in a digital environment. Real world objects are represented accurately in a virtual world digital environment. The digital environment can be updated based on real world conditions. The present systems and methods are configured to enable more accurate and realistic simulation with the real world objects and/or physical systems in the real world conditions compared to prior systems.

### BACKGROUND

### 1. Field

The present disclosure relates generally to digital model and digital twin generation using generative transformer networks and large language models.

### 2. Description of the Related Art

Large Language Models (LLM) are formed by a stack of transformer layers. They are trained for Natural Language Processing (NLP) tasks such as text generation, text summarization, text sentiment analysis, and text translation. Using a large corpus of data (e.g., from the internet) a LLM is able to learn various complex concepts. A LLM can accomplish various text related tasks given a prompt that shows examples of how to perform a task.

Digital twins of physical systems and digital models of real world environments can be configured to electronically represent real world objects such as rockets, rocket parts, radar, radar components, air craft, air craft components, vehicles, sensors, and/or any other physical, mechanical, or electrical components. Historically, these components were designed using pencil and paper, physically built, and then the design was tested and iterated. Now, computers are used to build models virtually using computer aided design, iterate the models virtually, and then fabricate the parts (e.g., via three dimensional (3D) printing and/or other operations). For example, computer aided drafting (CAD) tools such as Solidworks, Ansys, Matlab, Python, and/or field programmable gate array (FPGA) tools such as those from the Xilinx company that may be used. Virtual reality (VR) tools such as VR Forces may be used to provide a virtual environment with a library of models, but the code for these models is written by the user to describe various model parameters.

### SUMMARY

The following is a non-exhaustive listing of some aspects of the present techniques. These and other aspects are described in the following disclosure.

Digital model and digital twin generation using generative transformer networks and large language models is described. A digital twin generator is configured to generate a digital twin of a physical system useable for electronic testing with simulated real world conditions in a digital environment. Real world objects are represented accurately in a virtual world digital environment. The digital environment can be updated based on real world conditions. The present systems and methods are configured to enable more accurate and realistic simulation with the real world objects and/or physical systems in real world conditions, but in in the virtual world digital environment, compared to prior systems.

Some aspects include a non-transitory computer readable medium having instructions that, when executed by a computer, cause the computer to execute a digital twin generator. The digital twin generator is configured to generate a digital twin of a physical system useable for electronic testing with simulated real world conditions in a digital environment. The digital twin generator comprises a set of abstract classes associated with various physical systems and/or components of the various physical systems. An abstract class defines general base characteristics of the various physical systems, their components, and/or implementation of the various physical systems and/or their components in the simulated real world conditions. The digital twin generator comprises a trained parameterized model configured to receive user input specifying the real world conditions, the physical system for which the digital twin is generated, one or more modeled components of the physical system, characteristics of the physical system, characteristics of the one or more modeled components, and/or how the physical system and/or the one or more modeled components are to be implemented in the simulated real world conditions. The trained parameterized model is configured to determine an abstract class and/or classes for the physical system and/or the one or more modeled components based on the user input. The trained parameterized model is configured to generate code, starting from a determined abstract class and/or classes, and based on the user input, to define and customize the digital twin of the physical system for electronic testing with simulated real world conditions in the digital environment.

Some aspects include a non-transitory computer readable medium having instructions that, when executed by the computer, cause the computer to represent real world objects accurately in a virtual world digital environment. Such a representation may include a digital twin of a physical system, for example. The instructions cause the computer to receive first user input and/or sensor output signals specifying real world conditions for simulation in the virtual world digital environment, receive second user input and/or sensor output signals indicating presence of a real object in the real world, and execute the trained parameterized model, among other operations. The trained parameterized model is configured to generate the virtual world digital environment and simulate the real world conditions in the virtual world digital environment based on the first user input and/or sensor output signals; determine characteristics of the real object based on the second user input and/or sensor output signals; and generate a photo realistic representation of the real object in simulated real world conditions in the virtual world digital environment based on the second user input and/or sensor output signals and the characteristics of the real object. The photo realistic representation accurately reflects the characteristics of the real object such that the photo realistic representation interacts with the simulated real world conditions in the virtual world digital environment as the real object interacts with the real world conditions.

Some aspects include a non-transitory computer readable medium having instructions that, when executed by a computer, cause the computer to update a (virtual world) digital environment based on real world conditions. The instructions cause the computer to receive user and/or sensor input specifying the real world conditions, and execute the trained parameterized model, among other operations. The trained parameterized model is configured to generate code, based on the user and/or sensor input, to define and customize a digital environment to simulate the real world conditions; and automatically adjust simulated real world conditions in the digital environment based on additionally received actual data from the real world. Automatically adjusting comprises comparing data from the simulated real world conditions in the digital environment to the additionally received actual data from the real world, and adjusting the code for the simulated real world conditions in the digital environment such that data from the simulated real world conditions in the digital environment more closely matches the additionally received actual data from the real world.

In some embodiments, the trained parameterized model comprises a large language model. In some embodiments, the trained parameterized model comprises a generative transformer.

In some embodiments, the physical system comprises a rocket, radar, an aircraft, a vehicle, a sensor, and/or other physical systems. An object may be and/or include a portion of a physical system, a structure in and/or an element of the virtual world digital environment, and/or other objects.

In some embodiments, the digital twin generator comprises a model-view-controller framework. The model-view-controller framework comprises an application programming interface (API) configured to define: interactions between the components, elements, objects, the various physical systems, and/or the simulated real world conditions in the digital environment; positions of the components, elements, objects, and/or the various physical systems in the digital environment; a state of the components, elements, objects, the various physical systems, and/or the simulated real world conditions in the digital environment; and/or movement of the components, elements, objects, and/or the various physical systems through the digital environment. The model-view-controller framework comprises a user interface configured to generate a multidimensional representation of the components and/or the various physical systems for a visualization by a user; and a controller configured to control the interactions, positions, state, and movement of the components, elements, objects, and/or the physical systems in the simulated real world conditions in the digital environment over time. The trained parameterized model is configured to generate the code for use by the API, the user interface, and the controller for customizing the electronic testing of the digital twin with the simulated real world conditions in the digital environment according to the user input.

In some embodiments, a digital twin, and/or the electronic testing of the digital twin with the simulated real world conditions in the digital environment, comprises multiple levels of abstraction. A level of abstraction is configured to be entered and/or selected by the user via a user interface. The multiple levels of abstraction are associated with different time scales. A time scale is measured in years, months, weeks, days, hours, minutes, seconds, milliseconds, femtoseconds, and/or other increments. As an example, a physical system may be a quantum radar system and a level of abstraction of the electronic testing of a digital twin of the quantum radar system is on a femtosecond time scale.

In some embodiments, the simulated real world conditions in the digital environment comprise a physics based model of the simulated real world conditions in the digital environment.

In some embodiments, the trained parameterized model is further configured to be automatically adjusted to improve accuracy of the one or more modeled components in the simulated real world conditions over time.

In some embodiments, the trained parameterized model is configured to receive multi modal user inputs from the user. The multi modal user inputs may comprise at least two different input modality types. For example, the multi modal user inputs comprising the at least two different input modality types may include two or more of text, image, video, audio, and electromagnetic inputs. The electromagnetic inputs may comprise radiofrequency (RF) waves, light waves, infrared radiation, and/or other inputs. In some embodiments, the multi modal inputs comprising the at least two different input modality types include a first input comprising text, an image, a video, audio input, or an electromagnetic input, and a second input comprising a different one of the text, image, video, audio input, or electromagnetic input.

In some embodiments, the digital twin comprises an electronic model of the physical system, and the code comprises Python code.

In some embodiments, generating the photo realistic representation of a real object in the simulated real world conditions comprises implementing a simulation of the real object in the simulated real world conditions.

In some embodiments, the real world conditions comprise atmospheric weather related conditions, presence of other moving or stationary objects, presence of radiofrequency (RF) waves, presence of light waves, presence of infrared radiation, presence of environmental noise, and/or other conditions.

Some aspects include a method comprising one or more of the operations described above.

Some aspects include a system, including: one or more processors; and memory storing the instructions, such that when the instructions are executed by the processors, the instructions cause the processors to effectuate one or more of the operations described above.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 is a logical-architecture block diagram that illustrates a system configured to execute a digital twin generator configured to generate a digital twin of a physical system useable for electronic testing with simulated real world conditions in a digital environment, represent real world objects accurately in a virtual world in the digital environment, update the virtual world digital environment based on real world conditions, and/or perform other operations using a trained parameterized model.

FIG. 2 illustrates a digital twin low-fi sensor simulation and visualization framework.

FIG. 3 illustrates a first demonstration scenario, for a stationary sensor cluster digital twin.

FIG. 4 illustrates a second demonstration scenario, now for a mobile sensor cluster digital twin.

FIG. 5 illustrates a third demonstration scenario, for digital twins of multiple different sensor clusters.

FIG. 6 illustrates a fourth demonstration scenario, for a digital twin of a sensor cluster configured to sense information related to various airborne objects.

FIG. 7 is a schematic illustration of one possible example implementation of one or more components of the system shown in FIG. 1.

FIG. 8 illustrates an example software data flow in the system shown in FIG. 1.

FIG. 9 illustrates example views of a user interface that may be presented to a user to facilitate interaction with the system shown in FIG. 1.

FIG. 10 is a diagram that illustrates an exemplary computing system in accordance with embodiments of the present system.

FIG. 11 is a flowchart of a method for digital model and digital twin generation using generative transformer networks and large language models.

While the invention is susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the field of digital modeling, and digital twin generation, using generative transformer networks and large language models, and other fields. The inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

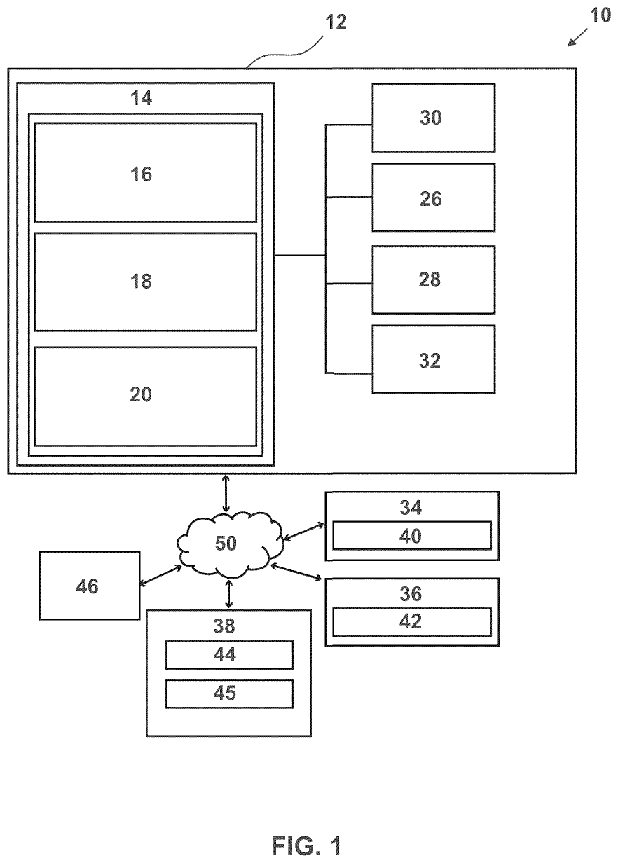

FIG. 1 illustrates a system 10 comprising a digital model and digital twin generation engine 12 and other components configured to execute a digital twin generator configured to generate a digital twin of a physical system useable for electronic testing with simulated real world conditions in a digital environment, represent real world objects accurately in a virtual world in the digital environment, update the virtual world digital environment based on real world conditions, and/or perform other operations using a trained parameterized model. This may allow a user to make various observations, perform various calculations, make various measurements, and/or perform other actions without physical real world systems.

System 10 is configured to function as a digital twin generator using a software infrastructure factory framework where component types inherit parameters from an existing library. System 10 is configured to generate any number of designs, and also facilitate human narrations of a design, via one or more trained parameterized models such as large language models (LLM) and/or generative transformer neural networks, for example. As described below, the digital twin generator uses a model view controller framework that includes an application programming interface (API) configured to define interactions between the components, the various physical systems, and/or the simulated real world conditions in the digital environment; positions of the components and/or the various physical systems in the digital environment; a state of the components, the various physical systems, and/or the simulated real world conditions in the digital environment; and/or movement of the components and/or the various physical systems through the digital environment. The model view controller framework also includes, provides, and/or otherwise controls a user interface configured to generate a multidimensional representation of the components and/or the various physical systems for a visualization by a user; and a controller configured to control the interactions, positions, state, and movement of the components and/or the physical system in the simulated real world conditions in the digital environment over time. A trained parameterized model is configured to generate code for use by the API, the user interface, and the controller for customizing the electronic testing of the digital twin with the simulated real world conditions in the digital environment according to the user input.

Advantageously, system 10 solves several problems. System 10 eliminates manual labor from coding and hand designing using CAD tools. System 10 comprises and/or otherwise defines a set of abstract classes associated with various physical systems and/or components of the various physical systems. An abstract class defines general base characteristics of the various physical systems, their components, and/or implementation of the various physical systems and/or their components in the simulated real world conditions. This reduces necessary computing capability (and also making system 10 faster than other systems) because system 10 does not have to start from “scratch” when building a digital twin. System 10 is also configured such that a user can “generate” models, views, and control operations with the model view controller framework using existing software infrastructure as well as with a generative network that builds models within the virtual software architecture.

In addition, system 10 is configured to integrate models from many different environments and tools into a single environment. For example, often Ansys is used for antenna design, Xilinx tools are used for FPGA design, Keysight tools are used for radiofrequency (RF) components design, Solidworks is used for mechanical design, and a coding environment is used for other software necessary for modeling. No single environment exists that combines tools like this.

Further, system 10 incorporates “hardware in the loop” seamlessly such that as hardware is built and/or otherwise utilized, data from the hardware can be seamlessly incorporated by system 10 such that a hybrid virtual environment is created where some of the components and objects in the environment, and/or various behaviors, interactions, etc., represent real objects generated based on real data (e.g., compared to modeled data). Inputs and outputs to and from system 10 and/or a virtual environment may be received from and/or provided to real hardware such as sensors, etc., through a network, using a “hardware in the loop” API, for example.

In system 10, a digital twin, and/or the electronic testing of the digital twin with the simulated real world conditions in the digital environment, comprises multiple levels of abstraction. The multiple levels of abstraction are associated with different time scales, and

wherein a time scale is measured in years, months, weeks, days, hours, minutes, seconds, milliseconds, femtoseconds, etc., As an example, physical system (for which a digital twin may be generated) could be a quantum radar system and a level of abstraction of the electronic testing of a digital twin of the quantum radar system may be on a femtosecond time scale.

The multi modal prompts described herein facilitate the use of any kind of data for commanding LLMs, the unlocking of potential new applications by skipping the need to finetune models for new data, avoid large training costs and deployment time (of LLMs and/or other models), and/or other advantages. The multi modal prompts described herein also facilitate decoupling training datasets from a particular application. A model (e.g., a LLM) may be trained to have generic associativity capabilities instead of mimicking a particular dataset. During model deployment, a user can provide examples with any kind data to tell what the model (e.g. the LLM) what to do. This makes a given model a more generic task solver, and/or has other advantages.

These and other benefits are described in greater detail below, after introducing the components of system 10 and describing their operation. It should be noted, however, that not all embodiments necessarily provide all of the benefits outlined herein, and some embodiments may provide all or a subset of these benefits or different benefits, as various engineering and cost tradeoffs are envisioned, which is not to imply that other descriptions are limiting.

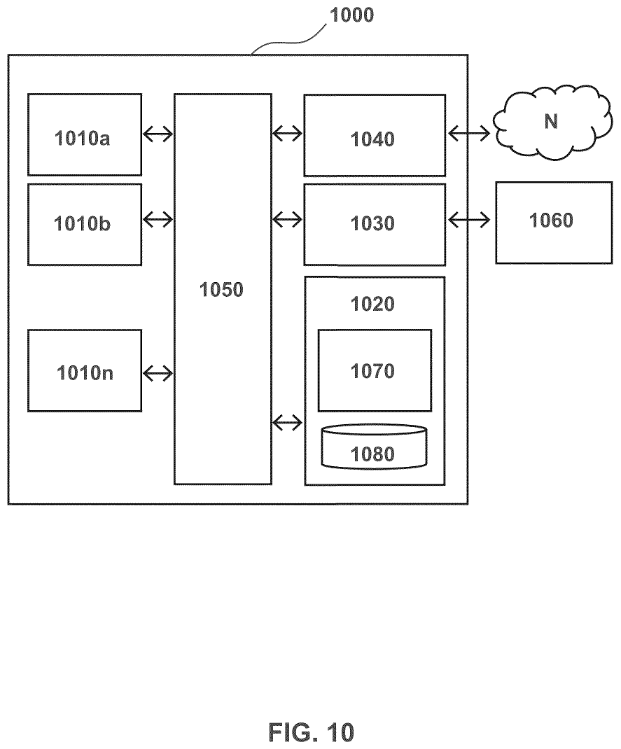

In some embodiments, engine 12 is executed by one or more of the computers described below with reference to FIG. 10 and may include one or more of a controller 14, an application program interface (API) server 26, a web server 28, a data store 30, and a cache server 32. These components, in some embodiments, communicate with one another in order to provide the functionality of engine 12 described herein.

Cache server 32 may expedite access to relevant data by storing likely relevant data in relatively high-speed memory, for example, in random-access memory or a solid-state drive. Web server 28 may serve webpages having graphical user interfaces that display one or more views that facilitate receiving entry or selection of input from a user (e.g., including a command that system 10 perform a certain task, context information, etc.), and/or other views. API server 26 may serve data to various applications that process data related to user requested tasks, or other data. The operation of these components 26, 28, and 30 may be coordinated by controller 14, which may bidirectionally communicate with each of these components or direct the components to communicate with one another. Communication may occur by transmitting data between separate computing devices (e.g., via transmission control protocol/internet protocol (TCP/IP) communication over a network), by transmitting data between separate applications or processes on one computing device; or by passing values to and from functions, modules, or objects within an application or process, e.g., by reference or by value.

In some embodiments, interaction with users and/or other entities may occur via a website or a native application viewed on a desktop computer, tablet, or a laptop of the user. In some embodiments, such interaction occurs via a mobile website viewed on a smart phone, tablet, or other mobile user device, or via a special-purpose native application executing on a smart phone, tablet, or other mobile user device. Data may be extracted by controller 14 and/or other components of system 10 from data store 30 and/or other sources inside or outside system 10 in a secure and encrypted fashion. Data extraction by controller 14 may be configured to be sufficient for system 10 to function as described herein, without compromising privacy and/or other requirements associated with a data source.

To illustrate an example of the environment in which engine 12 operates, the illustrated embodiment of FIG. 1 includes a number of components with which output engine 12 communicates: mobile user devices 34 and 36; a desk-top user device 38; and external resources 46. Each of these devices communicates with engine 12 via a network 50, such as the Internet or the Internet in combination with various other networks, like local area networks, cellular networks, Wi-Fi networks, or personal area networks.

Mobile user devices 34 and 36 may be smart phones, tablets, gaming devices, or other hand-held networked computing devices having a display, a user input device (e.g., buttons, keys, voice recognition, or a single or multi-touch touchscreen), memory (such as a tangible, machine-readable, non-transitory memory), a network interface, a portable energy source (e.g., a battery), and a processor (a term which, as used herein, includes one or more processors) coupled to each of these components. The memory of mobile user devices 34 and 36 may store instructions that when executed by the associated processor provide an operating system and various applications, including a web browser 42 and/or a native mobile application 40. The desktop user device 38 may also include a web browser 44 a native application 45, and/or other electronic resources. In addition, desktop user device 38 may include a monitor; a keyboard; a mouse; memory; a processor; and a tangible, non-transitory, machine-readable memory storing instructions that when executed by the processor provide an operating system and the web browser 44 and/or the native application 45.

Native applications and web browsers 40, 42, 44, and 45, in some embodiments, are operative to provide a graphical user interface associated with a user, for example, that communicates with engine 12 and facilitates user interaction with data from engine 12. In some embodiments, engine 12 may be stored on and/or otherwise be executed user computing resources (e.g., a user computer, server, etc., such as mobile user devices 34 and 36, and desktop user device 38 associated with a user), servers external to the user, and/or in other locations. In some embodiments, engine 12 may be run as an application (e.g., an app such as native application 40) on a server, a user computer, and/or other devices.

Web browsers 42 and 44 may be configured to receive a website from engine 12 having data related to instructions (for example, instructions expressed in JavaScript™) that when executed by the browser (which is executed by the processor) cause mobile user devices 34 and/or 36, and/or desktop user device 38, to communicate with engine 12 and facilitate user interaction with data associated with engine 12. Native application 40 and 45, and web browsers 42 and 44, upon rendering a webpage and/or a graphical user interface from engine 12, may generally be referred to as client applications of engine 12, which in some embodiments may be referred to as a server. Embodiments, however, are not limited to client/server architectures, and engine 12, as illustrated, may include a variety of components other than those functioning primarily as a server. Three user devices are shown, but embodiments are expected to interface with substantially more, with more than 100 concurrent sessions and serving more than 1 million users distributed over a relatively large geographic area, such as a state, the entire United States, and/or multiple countries across the world.

External resources 46, in some embodiments, include sources of information such as databases, websites, etc.; external entities participating with the system 10, one or more servers outside of system 10, a network (e.g., the internet), electronic storage, equipment related to Wi-Fi™ technology, equipment related to Bluetooth® technology, data entry devices, sensors and/or other sources that provide real world data associated with a certain digital twins and/or virtual environments, and/or other resources. In some implementations, some or all of the functionality attributed herein to external resources 46 may be provided by resources included in system 10. External resources 46 may be configured to communicate with engine 12, mobile user devices 34 and 36, desktop user device 38, and/or other components of the system 10 via wired and/or wireless connections, via a network (e.g., a local area network and/or the internet), via cellular technology, via Wi-Fi technology, and/or via other resources.

Thus, engine 12, in some embodiments, operates in the illustrated environment by communicating with a number of different devices and transmitting instructions to various devices to communicate with one another. The number of illustrated external resources 46, desktop user devices 38, and mobile user devices 36 and 34 is selected for explanatory purposes only, and embodiments are not limited to the specific number of any such devices illustrated by FIG. 1, which is not to imply that other descriptions are limiting.

Engine 12 may include a number of components introduced above that facilitate generating a digital twin of a physical system useable for electronic testing with simulated real world conditions in a digital environment, causing a computer to represent real world objects accurately in a virtual world digital environment, causing a computer to update a digital environment based on real world conditions, and/or other operations. For example, the illustrated API server 26 may be configured to communicate user input text commands, input images, and/or other information via a protocol, such as a representational-state-transfer (REST)-based API protocol over hypertext transfer protocol (HTTP) or other protocols. Examples of operations that may be facilitated by API server 26 include requests to generate a digital twin, requests to represent real world objects accurately in a virtual world digital environment, requests to update a digital environment based on real world conditions, etc. API requests may identify which output data is to be displayed linked, modified, added, or retrieved by specifying criteria for identifying tasks, such as queries for retrieving or processing information about a particular subject (e.g., parameters associated with a digital twin, a digital environment, etc.). In some embodiments, the API server 26 communicates with the native application 40 of the mobile user device 34, the native application 45 of the desktop user device 38, and/or other components of system 10.

The illustrated web server 28 may be configured to display, link, modify, add, or retrieve portions or all of a digital twin of a physical system useable for electronic testing with simulated real world conditions in a digital environment, a representation of a real world object accurately in a virtual world digital environment, updates to a digital environment based on real world conditions, and/or other information encoded in a webpage (e.g. a collection of resources to be rendered by the browser and associated plug-ins, including execution of scripts, such as JavaScript™, invoked by the webpage). In some embodiments, the graphical user interface presented by the webpage may include inputs by which the user may enter or select data, such as clickable or touchable display regions or display regions for text input. For example, user input specifying real world conditions, a physical system for which a digital twin is generated, one or more modeled components of the physical system, characteristics of the physical system, characteristics of the one or more modeled components, and/or how the physical system and/or the one or more modeled components are to be implemented in the simulated real world conditions may be provided. Such inputs may prompt the browser to request additional data from the web server 28 or transmit data to the web server 28, and the web server 28 may respond to such requests by obtaining the requested data and returning it to the user device or acting upon the transmitted data (e.g., storing posted data or executing posted commands). In some embodiments, the requests are for a new webpage or for data upon which client-side scripts will base changes in the webpage, such as XMLHttpRequest requests for data in a serialized format, e.g. JavaScript™ object notation (JSON) or extensible markup language (XML). The web server 28 may communicate with web browsers, such as the web browser 42 or 44 executed by user devices 36 or 38. In some embodiments, the webpage is modified by the web server 28 based on the type of user device, e.g., with a mobile webpage having fewer and smaller images and a narrower width being presented to the mobile user device 36, and a larger, more content rich webpage being presented to the desk-top user device 38. An identifier of the type of user device, either mobile or non-mobile, for example, may be encoded in the request for the webpage by the web browser (e.g., as a user agent type in an HTTP header associated with a GET request), and the web server 28 may select the appropriate interface based on this embedded identifier, thereby providing an interface appropriately configured for the specific user device in use.

The illustrated data store 30, in some embodiments, stores and/or is configured to access data required to generate a digital twin of a physical system useable for electronic testing with simulated real world conditions in a digital environment, cause a computer to represent real world objects accurately in a virtual world digital environment, cause a computer to update a digital environment based on real world conditions, and/or other operations. Data store 30 may include various types of data stores, including relational or non-relational databases; image, document, etc., collections; and/or programming instructions related to storage and/or execution of one or more of the models described herein, for example. Such components may be formed in a single database, or may be stored in separate data structures. In some embodiments, data store 30 comprises electronic storage media that electronically stores information. The electronic storage media of data store 30 may include one or both of system storage that is provided integrally (i.e., substantially non-removable) with system 10 and/or other storage that is connectable (wirelessly or via a wired connection) to system 10 via, for example, a port (e.g., a USB port, a firewire port, etc.), a drive (e.g., a disk drive, etc.), a network (e.g., the Internet, etc.). Data store 30 may be (in whole or in part) a separate component within system 10, or data store 30 may be provided (in whole or in part) integrally with one or more other components of system 10 (e.g., controller 14, external resources 46, etc.). In some embodiments, data store 30 may be located in a data center, in a server that is part of external resources 46, in a computing device 34, 36, or 38, and/or in other locations. Data store 30 may include one or more of optically readable storage media (e.g., optical disks, etc.), magnetically readable storage media (e.g., magnetic tape, magnetic hard drive, floppy drive, etc.), electrical charge-based storage media (e.g., EPROM, RAM, etc.), solid-state storage media (e.g., flash drive, etc.), or other electronically readable storage media. Data store 30 may store software algorithms, information determined by controller 14, information received via the graphical user interface displayed on computing devices 34, 36, and/or 38, information received from external resources 46, or other information accessed by system 10 to function as described herein. For example, data store 30 may store information associated with a set of abstract classes associated with various physical systems and/or components of the various physical systems. An abstract class may define general base characteristics of the various physical systems, their components, and/or implementation of the various physical systems and/or their components in the simulated real world conditions.

Controller 14 is configured to coordinate the operation of the other components of engine 12 to provide the functionality described herein. Controller 14 may be formed by one or more processors, for example. Controlled components may include one or more of a digital twin component 16, an accurate real world object representation component 18, an updating a digital environment based on real world conditions component 20, and/or other components. Controller 14 may be configured to direct the operation of components 16, 18, and/or 20 by software; hardware; firmware; some combination of software, hardware, or firmware; or other mechanisms for configuring processing capabilities.

It should be appreciated that although components 16, 18, and 20 are illustrated in FIG. 1 as being co-located, one or more of components 16, 18, and/or 20 may be located remotely from the other components. The description of the functionality provided by the different components 16, 18, and/or 20 described below is for illustrative purposes, and is not intended to be limiting, as any of the components 16, 18, and/or 20 may provide more or less functionality than is described, which is not to imply that other descriptions are limiting. For example, one or more of components 16, 18, and/or 20 may be eliminated, and some or all of its functionality may be provided by others of the components 16, 18, and/or 20, again which is not to imply that other descriptions are limiting. As another example, controller 14 may be configured to control one or more additional components that may perform some or all of the functionality attributed below to one of the components 16, 18, and/or 20. In some embodiments, engine 12 (e.g., controller 14 in addition to cache server 32, web server 28, and/or API server 26) is executed in a single computing device, or in a plurality of computing devices in a datacenter, e.g., in a service oriented or micro-services architecture.

Digital twin component 16 is configured to generate a digital twin of a physical system useable for electronic testing with simulated real world conditions in a digital environment (e.g., to facilitate making various observations, calculations, measurements, etc.). The digital twin may comprise an electronic model of the physical system, for example. The simulated real world conditions in the digital environment may comprise and/or be generated by a physics based model of the simulated real world conditions in the digital environment. An example of a physics based model is the model dictating the range of a radar. For example, there is a radar range equation, known in current literature, where the maximum range a radar can detect a target is in part dictated by the radar cross section of a target (describing the amount of electromagnetic energy the target reflects), the noise figure, or amount of thermal noise and other types of noise present in the atmosphere and in the radar system, the wavelength of the electromagnetic waves the radar is using as well as other attributes. Physical attributes the model can update in a closed loop way include, for example, the noise in the environment. As the present system measures the amount of noise in a real environment, the noise parameter in the physics based digital twin model can be updated. The physical system may be a rocket, radar, an aircraft, a vehicle, a sensor, and/or any other physical system (these are just several possible examples).

Component 16 comprises and/or is otherwise configured to access a set of abstract classes associated with various physical systems and/or components of the various physical systems. An abstract class defines general base characteristics of the various physical systems, their components, implementation of the various physical systems and/or their components in the simulated real world conditions, and/or other information. The abstract classes may be a set of classes that all objects (e.g., objects that make up one or more portions, or all of, a digital twin) can inherit characteristics, components, implementation parameters, etc., from—such as a mobility object, a timing object, a geographic/earth object, a sensor object, etc. An example of an abstract class is the sensor class. This sensor class may be abstract in that any instantiation of the sensor class must have a receiver component that can receive a signal through an aperture, where the sensor, signal type, and aperture type must be instantiated and described. A radar would be an instantiated version of the abstract “sensor” class where a receiver is implemented with a radar receiver, and the radar would receive electromagnetic signals of a certain frequency. Further, this radar receiver may instantiate multiple radio frequency antennas as its apertures.

Component 16 comprises and/or is otherwise configured to access and/or execute one or more trained parameterized models. The trained parameterized model(s) are configured to receive user input specifying real world conditions, a physical system for which a digital twin is generated, one or more modeled components of the physical system, characteristics of the physical system, characteristics of the one or more modeled components, how the physical system and/or the one or more modeled components are to be implemented in the simulated real world conditions, and/or other information. The trained parameterized model(s) are configured to determine an abstract class and/or classes for the physical system and/or the one or more modeled components based on the user input and/or other information. A trained parameterized model may determine an abstract class or classes based on training and/or other information. A model may be trained with training data comprising known labeled inputs and corresponding outputs that should be provided by the model. For example, a user may input specific real world conditions, a certain physical system for which a digital twin is to be generated, one or more specific components of the physical system, certain characteristics of the physical system, certain characteristics of the one or more modeled components, specific information about how the physical system and/or the one or more modeled components are to be implemented in the simulated real world conditions, and/or other information; and a corresponding abstract class or classes associated with each input that the model should output.

In some embodiments, the trained parameterized model(s) are configured to receive multi modal user inputs from the user. Multi modal user inputs comprise at least two different input modality types. For example, multi modal user inputs comprising at least two different input modality types may include two or more of text, image, video, audio, signal, byte sequence, code, electromagnetic, and/or other inputs. As one possible example, the electromagnetic inputs may comprise radiofrequency (RF) waves, light waves, infrared radiation, and/or other inputs. Such electromagnetic inputs may be received from a sensor included in external resources 46, for example, and/or from other sources. Inputs with other modality types may be received from a user, other external resources 46, and/or from other sources. In some embodiments, multi modal using inputs comprising at least two different input modality types include a first input comprising text, an image, a video, audio input, or an electromagnetic input, and a second input comprising a different one of the text, image, video, audio input, or electromagnetic input. For example, a multi modal input may include a user annotated (e.g., text) data stream from a low-fi electromagnetic sensor (e.g., an electromagnetic input) included in external resources 46.

The trained parameterized model(s) are configured to generate code, starting from a determined abstract class and/or classes, and based on the user input, to define and customize the digital twin of the physical system for electronic testing with simulated real world conditions in the digital environment. The trained parameterized model(s) may generate code by accessing a code repository that stores different code for different abstract classes, generating new code modeled after previously generated code for the same or similar abstract classes, etc., These actions may be thought of as “inheriting” previous code generated for the same or similar abstract classes, such that less computing power is required to generate the code (e.g., because component 16 is not starting from scratch). Component 16 may be configured such that only certain parameters of the generated code may need to be generated and/or adjusted based on the user input and/or other information, for example. The code may comprise Python code, and/or other code. For example, the trained parameterized model(s) may receive an input from a user that specifies what kind of object the user wants to model in a virtual world, and generate the python code by obtaining information from a library (e.g., associated with a certain abstract class). Component 16 may generate a view of a corresponding digital twin, and instantiate it using the algorithms in the software framework described herein.

In some embodiments, the trained parameterized model(s) comprise a large language model. In some embodiments, the trained parameterized model(s) comprise a generative transformer. A generative transformer is good at detecting a pattern of symbols and continuing to build a sequence symbols. One example is written English language where the symbols are letters and words. A multi-modal generative transformer can take inputs of multiple different types and/or translate that input into an output symbol of a different type or of multiple different types. In some embodiments, a user can input typed English language and output a series of instantiated models (generated from our abstract classes), such that a digital twin model can be created very quickly. In some embodiments, the trained parameterized model(s) comprise encoders, decoders, neural networks, and/or other components. For example, an encoder may be configured to encode an input into a low dimensional encoding or embedding space. In some embodiments, the low dimensional embedding represents one or more features of an input. The one or more features of the input may be considered key or critical features of the input. Features may be considered key or critical features of an input because they are relatively more predictive than other features of a desired output (e.g., a certain abstract class and/or associated code) and/or have other characteristics, for example. The one or more features (dimensions) represented in the low dimensional embedding may be predetermined (e.g., by a programmer at the creation of the present modular autoencoder model), determined and/or otherwise learned by prior layers of a neural network, adjusted by a user via a user interface associated with a system described herein, and/or may be determined in by other methods. In some embodiments, a quantity of features (dimensions) represented by the low dimensional embedding may be predetermined (e.g., by the programmer at the creation of the present modular autoencoder model), determined based on output from prior layers of the neural network, adjusted by the user via the user interface associated with a system described herein, and/or determined by other methods.

In some embodiments, encoder decoder architecture may be provided by and/or within one or more portions of a parameterized model such as a large language model, a generative transformer, one or more neural networks, etc., However, it should be noted that even though a large language model, generative transformer, neural network, and/or encoder decoder architecture are mentioned in this specification, the operations described herein may be applied to different parameterized models (e.g., other machine learning models).

Continuing the discussion of training from above, training of the parameterized model(s) may be supervised or unsupervised. In some embodiments, training configures the parameterized model(s) to learn a generic associativity of inputs, and once trained, to be deployed to output the abstract classes and/or associated code, without finetuning on new inputs. The parameterized model(s) are trained and/or otherwise configured to solve a task involving new inputs by finding a closest match to the input in an embedding space, and then assigning the input to a most relevant class based on a similarity of the input to the most relevant class. In some embodiments, component 16 may be configured to train the parameterized model(s) initially using input output training pairs and/or other information that provide an expected output based on a provided input, and/or other data.

In some embodiments, the parameterized model may comprise one or more individual algorithms (e.g., that form a LLM, a transformer, a neural network, etc.). In some embodiments, an algorithm may be a machine learning algorithm. In some embodiments, the machine learning algorithm may be or include a neural network, classification tree, decision tree, support vector machine, or other model that is trained and configured to output an abstract class and/or generate code in response to a given input. As an example, neural networks may be based on a large collection of neural units (or artificial neurons). Neural networks may loosely mimic the manner in which a biological brain works (e.g., via large clusters of biological neurons connected by axons). Each neural unit of a neural network may be simulated as being connected with many other neural units of the neural network. Such connections can be enforcing or inhibitory in their effect on the activation state of connected neural units. In some embodiments, each individual neural unit may have a summation function which combines the values of all its inputs together. In some embodiments, each connection (or the neural unit itself) may have a threshold function such that the signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for neural networks may be more free flowing, with connections interacting in a more chaotic and complex fashion.

Component 16 comprises and/or otherwise executes a model-view-controller framework. The model-view-controller comprises an application programming interface (API), for example provided by API server 26, configured to define interactions between the components, the various physical systems, and/or the simulated real world conditions in the digital environment; positions of the components and/or the various physical systems in the digital environment; a state of the components, the various physical systems, and/or the simulated real world conditions in the digital environment; movement of the components and/or the various physical systems through the digital environment; and/or other information. Component 16 may provide (and/or interact with other components of engine 12 to provide) a user interface (e.g., displayed via mobile user devices 34 and 36; a desk-top user device 38; etc.) configured to generate a multidimensional representation of the components and/or the various physical systems for visualization by a user. The representation may include a three dimensional (3D) rendering that maps various two dimensional (2D), 3D, and/or other inputs (e.g., as described above) to one or more portions of (e.g., an object in the representation), and/or all of the multidimensional representation.

Component 16 (part of controller 14 described above) is configured to control the interactions, positions, state, and movement of the components and/or the physical system (e.g., the digital twin) in the simulated real world conditions in the digital environment over time. The trained parameterized model(s) are configured to generate the code for use by the API, the user interface, and the controller for customizing the electronic testing of the digital twin with the simulated real world conditions in the digital environment according to the user input.

In some embodiments, component 16 is configured such that a digital twin, and/or the electronic testing of the digital twin with the simulated real world conditions in the digital environment, comprises multiple levels of abstraction. A level of abstraction may be configured to be entered and/or selected by the user via a user interface and/or determined by other operations. In some embodiments, the multiple levels of abstraction are associated with different time scales, such as time scales measured in years, months, weeks, days, hours, minutes, seconds, milliseconds, femtoseconds, and/or other time scales. As an example, a physical system may be a quantum radar system and a level of abstraction of the electronic testing of a digital twin of the quantum radar system is on a femtosecond time scale.

In some embodiments, component 16 (e.g., working in conjunction with one or more of the other components described herein) is configured such that the digital twin, and/or the electronic testing of the digital twin with the simulated real world conditions in the digital environment, are configured to be automatically adjusted based on received actual data from the real world. Automatically adjusting may comprise comparing data from the digital twin and/or the electronic testing of the digital twin with the simulated real world conditions in the digital environment to received actual data from the physical world (e.g., data from one or more sensors and/or other sources of information included in external resources 46), and adjusting the code for the digital twin and/or code associated with the simulated real world conditions in the digital environment such that data from the electronic testing of the digital twin with the simulated real world conditions in the digital environment more closely matches the received actual data from the real world. In some embodiments, adjusting the code for a digital twin and/or the code associated with the simulated real world conditions in the digital environment comprises changing a parameter of the digital twin and/or the simulated real world conditions in the digital environment. In some embodiments, component 16 may be configured such that the trained parameterized model(s) are configured to be automatically adjusted to improve accuracy of the one or more modeled components in the simulated real world conditions over time.

In general, component 16 forms a “digital twin factory” using the software infrastructure factory framework described herein where portions and/or all of a digital twin “inherit” various characteristics from existing source(s) (e.g., associated with an abstract class or classes). Component 16 is configured to generate a digital twin, and facilitate user “narration” of the design (e.g., via the API and interface described herein), utilizing large language models (LLM), generative transformer neural networks, etc.

As described above, component 16 uses a model view controller framework whereby there is an underlying physical model whose output can be simulated, such that calculations for the digital twin in the simulated environment can be performed, virtual measurements can be taken, and/or other operations may occur. A 3D model (e.g., a view of the digital twin) can be rotated and viewed in the virtual world. Component 16 enables simulations with the digital twin, including simulations that progress through time and cause a digital twin to interact with a virtual environment and/or with other virtual objects (which again facilitates calculations, measurements, etc.).

Component 16 may be thought of as integrating information from many different environments and tools into a single framework. For example, component 16 integrates aspects of Ansys which is used for antenna (e.g., as one example of physical system that may be the basis for a digital twin) design, Xilinx tools used for FPGA design, Keysight tools used for radiofrequency (RF) component design, solid works used for mechanical design, a coding environment used for software coding, and/or other integration of heterogenous models into a single environment.

Accurate real world object representation component 18 is configured to represent real world objects (e.g., which may or may not be part of a digital twin) accurately in a virtual world digital environment (e.g., to facilitate making various observations, calculations, measurements, etc.). This representation may be provided via the user interface described above (e.g., in combination with information from component 16 and displayed by mobile user devices 34 and/or 36, a desk-top user device 38, etc.). For example, component 18 may be configured to receive user input (e.g., as described above), sensor output signals (e.g., from sensors, databases, servers, etc., that are part of external resources 46), and/or other information specifying real world conditions for simulation in a virtual world digital environment. Component 18 may receive additional user input, sensor output signals, etc. (e.g., from the same or similar sources of information), indicating presence of a real object in the real world. Component 18 may execute the one or more trained parameterized model(s) (e.g., an LLM, a generative transformer, a neural network, encoders, decoders, etc., trained as described above) to generate the virtual world digital environment and simulate the real world conditions in the virtual world digital environment based on the user input, sensor output signals, etc. The parameterized model(s) are trained to determine characteristics of the real object based on the user input, sensor output signals, etc.; and generate a photo realistic representation of the real object in simulated real world conditions in the virtual world digital environment. The photo realistic representation is configured to accurately reflect the characteristics of the real object such that the photo realistic representation interacts with the simulated real world conditions in the virtual world digital environment as the real object interacts with the real world conditions.

In some embodiments, generating the photo realistic representation of the real object in the simulated real world conditions comprises implementing a simulation of the real object in the simulated real world conditions. In some embodiments, the simulated real world conditions in the virtual world digital environment comprise a physics based model of the simulated real world conditions in the virtual world digital environment. In some embodiments, a physics based model is written in the python computer programming language, which describes the physics of the radar range equation, as one example, and the parameters in the radar range equation that describe the physical environment and the physics equations dictating propagation of electromagnetic waves.

In some embodiments, the real world conditions comprise atmospheric weather related conditions, presence of other moving or stationary objects, presence of radiofrequency (RF) waves, presence of light waves, presence of infrared radiation, presence of environmental noise, and/or other information. As described above, the real object may comprise one or more portions, and/or an entirety of a rocket, radar, an aircraft, a vehicle, a sensor, and/or other objects. These are examples only. Several other possible real world conditions and/or objects exist.

In some embodiments, component 18 may be configured to coordinate with component 16 so that the photo realistic representation comprises a digital twin generated by component 16 (e.g., the digital twin generator) via the abstract classes, the trained parameterized model(s), the code, the model-view-controller framework, the API, the multi modal user inputs, etc., described herein.

Updating a digital environment based on real world conditions component 20 is configured to, as its name implies, update a digital environment based on real world conditions (e.g., to facilitate making various observations, calculations, measurements, etc.). Component 20 is configured to receive user, sensor, and/or other input (e.g., from sensors, databases, servers, etc., that are part of external resources 46) specifying the real world conditions (e.g., similar to and/or the same as what is described above for components 18 and/or 16). Component 20 may execute the one or more trained parameterized model(s) (e.g., an LLM, a generative transformer, a neural network, encoders, decoders, etc., trained as described above) to generate code (e.g., Python code similar to and/or the same as the code generation described above), based on the user, sensor, and/or other input, to define and customize a digital environment to simulate the real world conditions.

Similar to the automatic adjusting performed by component 18, component 20 may be configured to automatically adjust simulated real world conditions in the digital environment based on additionally received actual data from the real world (e.g., again from sensors, databases, servers, etc., that are part of external resources 46) and/or other information. Automatically adjusting comprises comparing data from the simulated real world conditions in the digital environment to the additionally received actual data from the real world, and adjusting the code for the simulated real world conditions in the digital environment such that data from the simulated real world conditions in the digital environment more closely matches the additionally received actual data from the real world. In some embodiments, adjusting the code comprises changing a parameter of the simulated real world conditions in the digital environment, for example.

In some embodiments, component 20 may be configured to coordinate with components 18 and/or 16 so that the simulated real world conditions in the digital environment comprise multiple levels of abstraction (e.g., different time scales measured in years, months, weeks, days, hours, minutes, seconds, milliseconds, femtoseconds, etc., as described above). Again the simulated real world conditions in the digital environment may comprise a physics based model of the simulated real world conditions in the virtual world digital environment (e.g., also as described above). In some embodiments, component 20 may be configured to coordinate with components 18 and/or 16 to receive the multi modal user inputs, etc. (and provide them to the trained parameterized model(s), described herein.

Since components 20, 18, and/or 16 incorporate from sensors, databases, servers, etc., that are part of external resources 46, for example, system 10 may be though of as having “hardware in the loop” and may be configured such that as hardware (sensors, databases, servers, etc.,) is built up, the hardware (and/or data and/or other information from the hardware) can be seamlessly accessed and/or otherwise used for one or more of the operations described herein such that a “hybrid” virtual environment is created where some of the components and objects in the environment actually represent real objects, and some are purely simulated, where the data, inputs and outputs to and from the virtual environment are connected to real hardware such as through the network shown in FIG. 1, using a “hardware in the loop” API, for example.

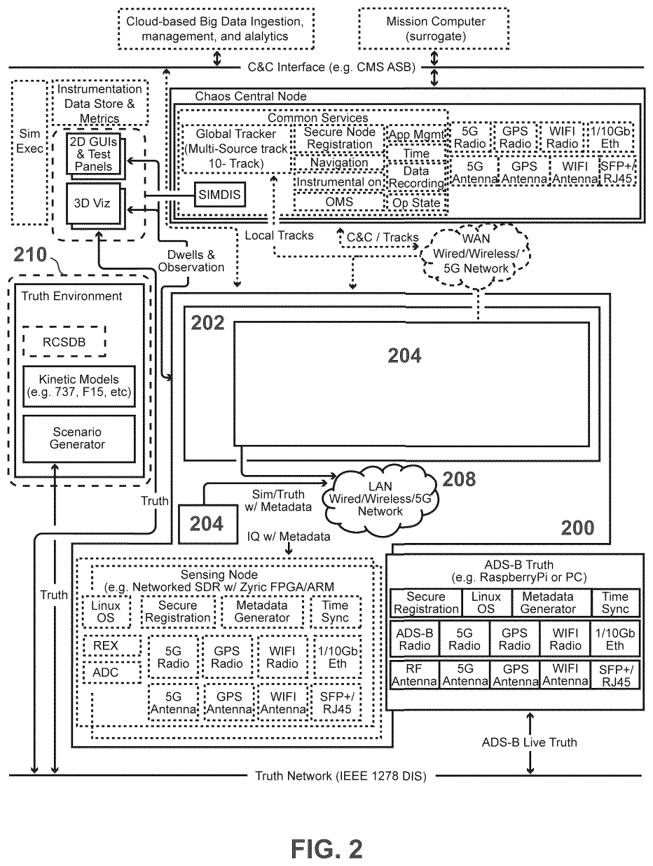

FIG. 2-FIG. 9 illustrate various examples of the various parts of system 10 shown in FIG. 1, and/or operations performed by those components.

For example, FIG. 2 illustrates a digital twin low-fi sensor simulation and visualization framework. Specifically, FIG. 2 illustrates initial sensor cluster model integration library component (MIL) integration with live virtual constructive (LVC), which is a module for creating and constructing the simulation and visualization framework. FIG. 2 illustrates several elements that may form some or all of components 16-18, controller 14, external resources 46, network 50, engine 12, computers 34-38, and/or other components inside or outside of system 10 shown in FIG. 1. A sensor cluster low-fi simulator 200 is illustrated, which includes a simulated sensing cluster compute node 202, and a low-fidelity cluster radar model 204. These communicate with a simulated sensing node 206 (which acts as a truth filter for a radar model) and may include simulated coms, GPS, etc., outputting simulation and/or truth data, with metadata. FIG. 2 also illustrates a LAN wired/wireless 5G network 208, a truth environment 210 (which may be provided by MAK Technologies, for example), among many other possible labeled components. These components may provide initial sensor cluster MIL integration with LVC simulation and visualization tools. A composable sensor cluster (configuration, arrangement, characteristics) may be provided with a low-fidelity radar model that perceives a virtual environment and computes observations. Nodes can be “mounted” to any simulated entity w/in a variety of virtual environments. This may include concept of operation (CONOPS)-based virtual scenario authoring and real-time playback (VR-Forces), information associated with aircraft entities from a real-time ADS-B feed (adsb_to_dis script). Recording and playback of virtual scenarios/environments may be provided (e.g., via a logger and/or other components). In some embodiments, 2D and 3D views of a scenario and/or a virtual environment may be provided (e.g., via VR-Forces, SIMDIS, etc.). VR-Forces, short for Virtual Reality Forces, and SIMDIS, short for simulation and display, are examples of commercially available software tools that a digital twin (generated as described herein) may interoperate with to help visualize the digital twin. A custom SIMDIS plug-in may incorporate sensor cluster observations into a 3D view. In general, this digital twin architecture, design, and implementation facilitates increased model fidelity and analysis capabilities.

In summary, FIG. 2 shows computer code that is used to describe the attributes of sensor nodes such as their output power, Radio frequency, antenna parameters and other important attributes, and the physics based models of how these sensors interact with the environment (e.g. electromagnetic waves propagating through the atmosphere. This may be thought of as an overall model. This overall model description interacts with both truth data, or sensor data collected from the real world and fed into a digital twin to be processed by generated computer code, as well as simulated data, or data produced by a simulated environment. The computer code representing our overall model processes either the simulated or truth data and can then also compare its results. As an example, the overall model may compute based in the input data it receives, the detection of an airborne object, and the overall model can then compare this to where the object actually was in real life or where it was in the simulated world to understand the accuracy of how well the overall model was able to detect a target.

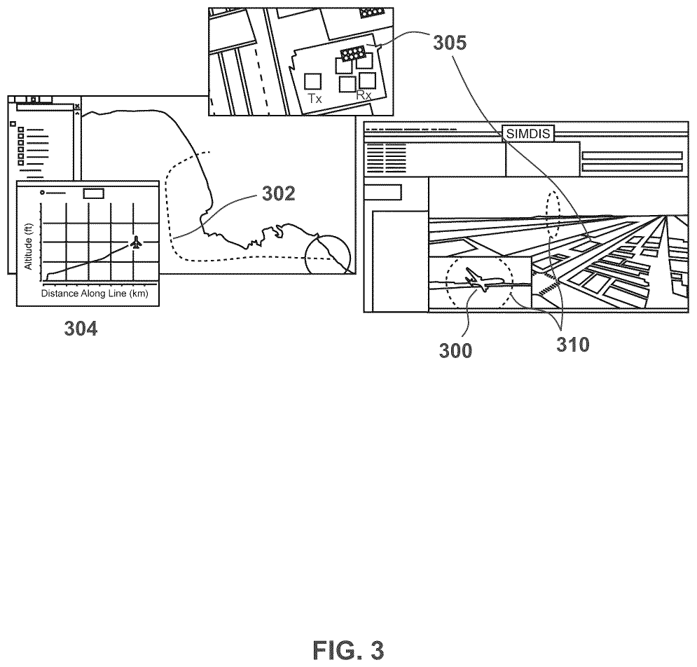

FIG. 3 illustrates a first demonstration scenario, for a stationary sensor cluster digital twin. FIG. 3 illustrates a simulated aircraft 300, a flightpath 302 (including altitude indication 304) for simulated aircraft 300, and simulated roof top sensor node standalone sensor assemblies 305, where Tx is short for transmit, and Rx is short for receive, along with sensor cluster (simulated) generated observations 310 (e.g., as described above). In some embodiments, digital twin component 16 (FIG. 1) is configured to generate a digital twin of a physical system (e.g., sensor assemblies 305 in this example) useable for electronic testing with simulated real world conditions in a digital environment (e.g., as shown in FIG. 3). Accurate real world object representation component 18 is configured to represent real world objects (e.g., sensor assemblies 305, aircraft 300, etc.) accurately in the virtual world digital environment. This representation may be provided via the user interface described above (e.g., in combination with information from component 16 and displayed by mobile user devices 34 and/or 36, a desk-top user device 38, etc. as shown in FIG. 1). User input (e.g., as described above), sensor output signals (e.g., from sensors, databases, servers, etc., that are part of external resources 46), and/or other information may be received that describe characteristics of sensor assemblies 305, aircraft 300 (e.g., the flightpath and altitude in this example), real world conditions, and/or other information for simulation in a virtual world digital environment. FIG. 3 also illustrates an example of a photo realistic representation of aircraft 300. FIG. 3 shows a virtual map representation of the real 3-dimensional world. This shows the overall model and computer code can detect an object using real sensor data, locate it in the real world, and then place it in its corresponding location in our virtual map representation. These real detections can then be augmented with virtual objects, where this mode is called “mixed reality”.

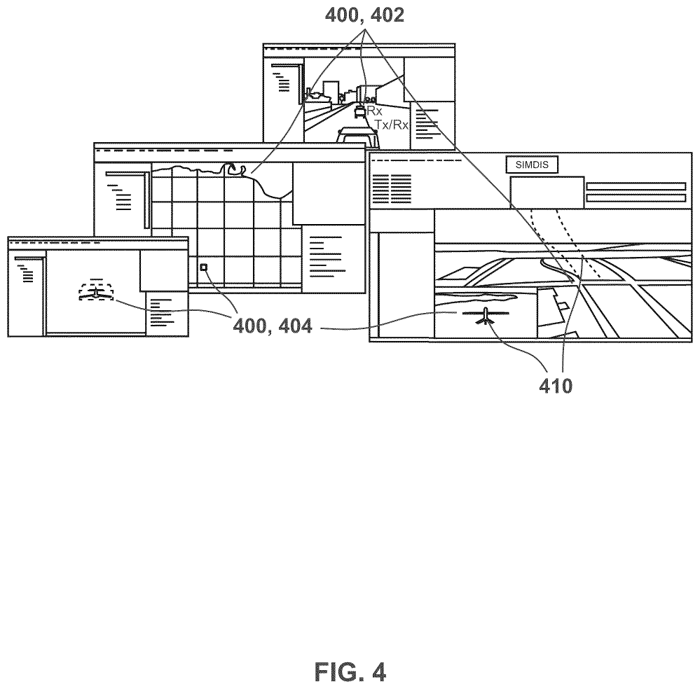

FIG. 4 illustrates a second demonstration scenario, now for a mobile sensor cluster digital twin. FIG. 4 illustrates mobile sensor clusters 400 mounted to simulated convoy vehicles 402 and a simulated unmanned aerial vehicle 404, along with sensor cluster (simulated) generated observations 410 and/or perform other operations including calculations, measurements, etc. As with FIG. 3, digital twin component 16 (FIG. 1) is configured to generate a digital twin of a physical system (e.g., mobile sensor clusters 400 in this example) useable for electronic testing with simulated real world conditions in a digital environment (e.g., as shown in FIG. 4). Accurate real world object representation component 18 is configured to represent real world objects (e.g., clusters 400, vehicles 402, vehicle 404, etc.) accurately in the virtual world digital environment. This representation may be provided via the user interface described above (e.g., in combination with information from component 16 and displayed by mobile user devices 34 and/or 36, a desk-top user device 38, etc. as shown in FIG. 1). User input (e.g., as described above), sensor output signals (e.g., from sensors, databases, servers, etc., that are part of external resources 46), and/or other information may be received that describe characteristics of sensor clusters 400, vehicles 402, vehicle 404, real world conditions, and/or other information for simulation in a virtual world digital environment. FIG. 4 is showing several moving objects. One of the parameters a digital twin uses to represent complex environments is that moving objects are simulated moving through the virtual world. In one embodiment, sensors are placed on these moving vehicles, the velocity of these vehicles are recorded and the inputs the sensor receives change based on the motion in the virtual world.

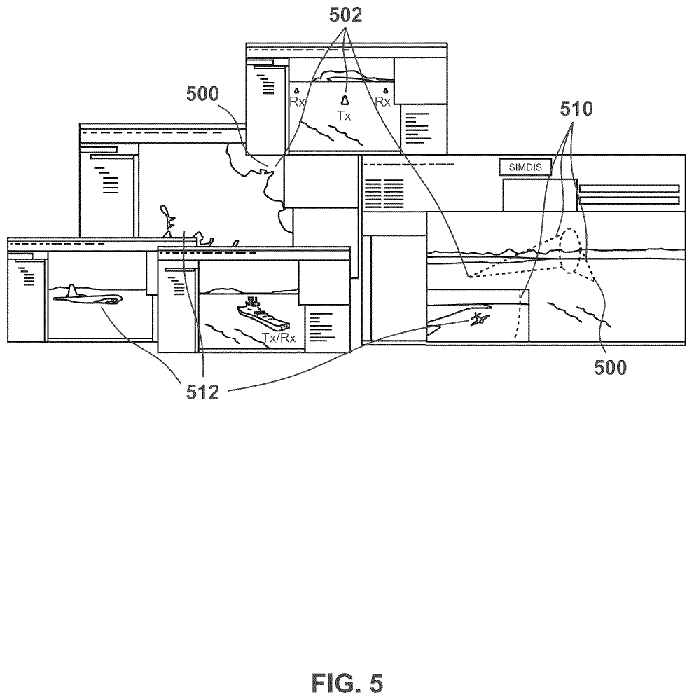

FIG. 5 illustrates a third demonstration scenario, for digital twins of multiple different sensor clusters 500 and 502. Clusters 500 and 502 may be located on buoys, ships, and/or other objects as shown in this example. Digital twins of multiple different sensor clusters 500 and 502 may be used to generate observations 510 and/or perform other operations including calculations, measurements, etc. As with FIGS. 3 and 4, digital twin component 16 (FIG. 1) is configured to generate a digital twin of a physical system (e.g., clusters 500 and 502 in this example) useable for electronic testing with simulated objects such as buoys, ships, and aircraft in this example (FIG. 5 illustrates an aircraft 512) associated with real world conditions (a real world flight plan in this example) in a digital environment (e.g., as shown in FIG. 5). Accurate real world object representation component 18 (FIG. 1) is configured to represent all of these real world objects accurately in the virtual world digital environment. Updating a digital environment based on real world conditions component 20 (FIG. 1) is configured to update the digital environment based on real world conditions (e.g., to facilitate making various observations, calculations, measurements, etc.). In this example, that may include weather and/or sea conditions, updates to the flight plan for aircraft 512, etc. FIG. 5 shows an airborne version of a moving object, whereas FIG. 4 shows ground based moving objects. FIG. 5 also shows that a real world detection was made, associated with a virtual object and this detection of a real object is placed in the digital twin virtual environment at its corresponding location using a representative symbol. Any symbol can be used to represent the detection. For example, if a commercial aircraft is detected in the real world, this detection can be represented in the real world with a military aircraft type if the user wanted to use commercial aircraft detections in the real world to simulate a military aircraft.

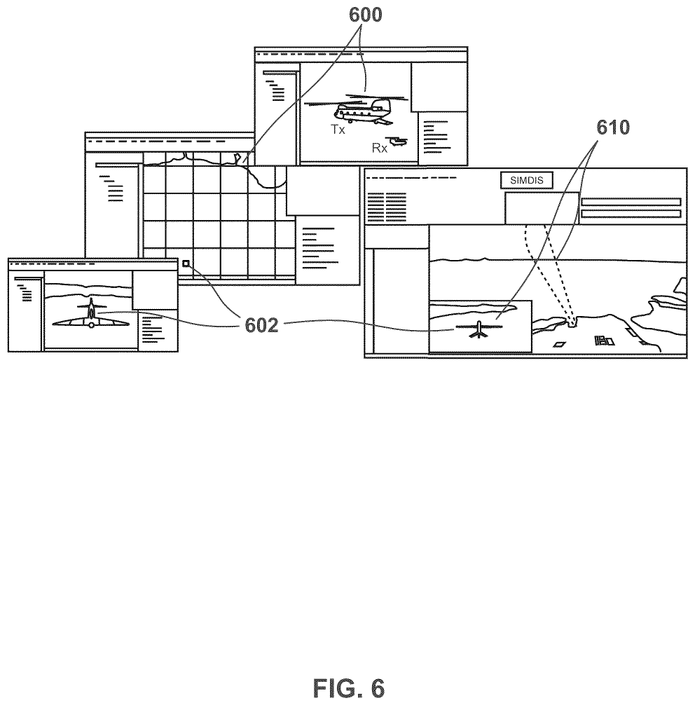

FIG. 6 illustrates a fourth demonstration scenario, for a digital twin of a sensor cluster configured to sense information related to various airborne objects. The various airborne objects include a helicopter 600 (delivering paratroopers) and an unmanned aerial vehicle 602 in this example. The digital twin of the sensor cluster may be used to generate observations 610 (and/or perform other operations including calculations, measurements, etc.). As with prior figures, digital twin component 16 (FIG. 1) is configured to generate a digital twin of a physical system (e.g., the sensor cluster in this example) useable for electronic testing with simulated objects such as helicopters, paratroopers, and unmanned aerial vehicles in this example, having associated flight paths and/or other relevant characteristics. Accurate real world object representation component 18 (FIG. 1) is configured to represent all of these real world objects accurately in the virtual world digital environment. Updating a digital environment based on real world conditions component 20 (FIG. 1) is configured to update the digital environment based on real world conditions (e.g., to facilitate making various observations, calculations, measurements, etc.). Element 610 in FIG. 6 shows a virtual beam, where the size, shape, dimensions of the beam are described by a physical model. In the case of a radar beam, the length and shape of the beam is dictated by the power out and effective radiated power parameters, as well as number of antenna elements in the antenna array, the frequency of the antenna array, and other parameters.

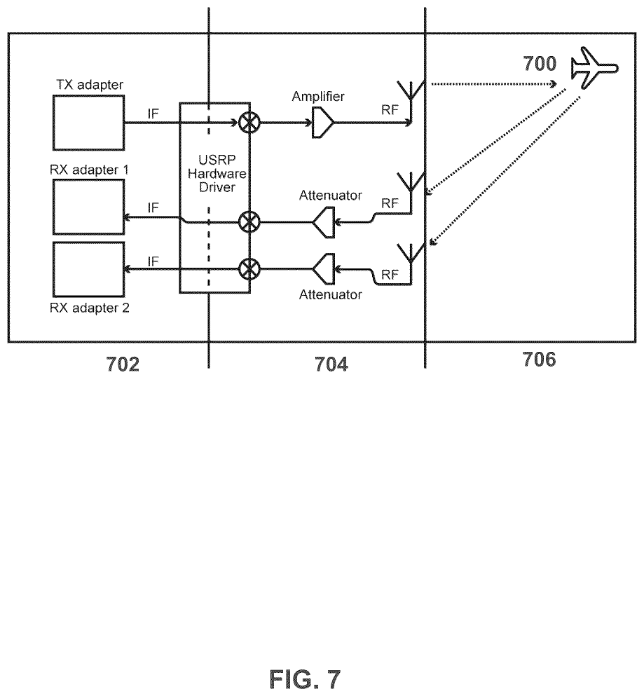

FIG. 7 is a schematic illustration of one possible example implementation of one or more components of engine 12 of system 10 shown in FIG. 1. FIG. 7 again illustrates aspects of a digital twin of a sensor (e.g., similar to the sensors and/or sensor clusters discussed above). The digital twin of the sensor is used to sense, observe, measure, calculate, etc. information related to an aircraft 700 in this example. FIG. 7 illustrates a sensor software portion 702, a high fidelity simulation portion 704, and a truth portion 706. Sensor software portion 702 comprises sensor code that is the same regardless of whether a simulation is running, or whether the sensor code is being used for real life detections. In this example, sensor software portion 702 includes a Tx adapter, a first Rx adapter, a second Rx adapter, and/or other components. IF is intermediate frequency. A digital twin generated as described herein simulates at all levels of fidelity, such that the internal workings of the sensor technology can be simulated such as the radio frequency chain in the radar, where the incoming radio frequency (RF) signal is down converted to an intermediate frequency (IF) with a simulated mixer and then digitized into complex inphase and quadrature (IQ) data. High fidelity simulation portion 704 is configured to scale IQ power levels for attenuation/amplification, generate a response IQ based on target (e.g., aircraft 700 in this example) and antennae position, report time based on delays and a virtual sync, and/or perform other operations. In this example, a software defined radio such as the universal software-defined radio product (USRP), also called a software defined radio (SDR) hardware driver is positioned in both high fidelity simulation portion 704 and sensor software portion 702. Truth portion 706 provides antennae and target positions, velocities, and other data that affect a signal (e.g., moisture in the air, clutter, etc.).

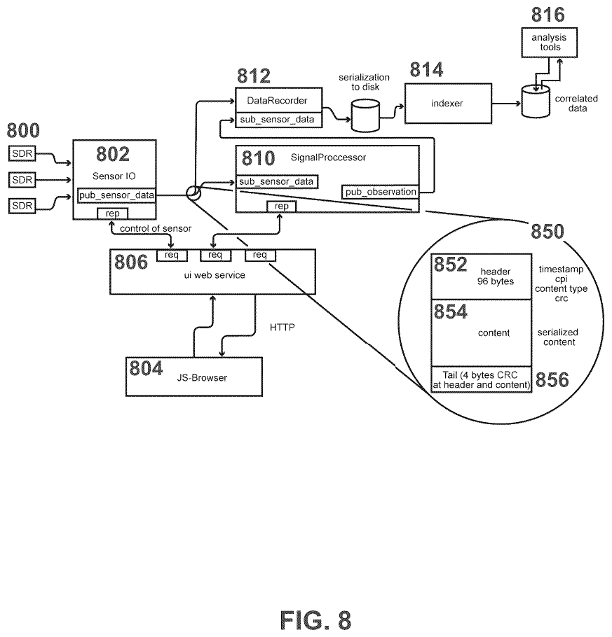

FIG. 8 illustrates an example software data flow in system 10 (FIG. 1). FIG. 8 illustrates various software defined radio (SDR)'s 800 which communicate with a sensor IO (input/output) 802. FIG. 8 illustrates a javascript (JS) browser 804 that communicates with a user interface (ui) web service 806 (e.g., via HTTP communications). The user interface web service 806 communicates with sensor IO 802 and a signal processor 810. The signal processor 810 and sensor IO 802 communicate with a data recorder 812, and in turn an indexer 814, and analysis tools 816. In FIG. 8, “rep” and “req” stand for response and request, such as in a client server architecture, respectively. Public sensor data (pub_sensor_data) is provided to data recorder 812 and signal processor 810. Signal processor 810 in turn provides observations (pub_observations) to data recorder 812. The public sensor data may be provided in a common message format 850 comprising a header 852, content 854, and a tail 856, for example. Note that the components shown in FIG. 8, the quantities of each component, the arrangement of each component, and/or the connections between each component, are just examples. Other configurations are possible.

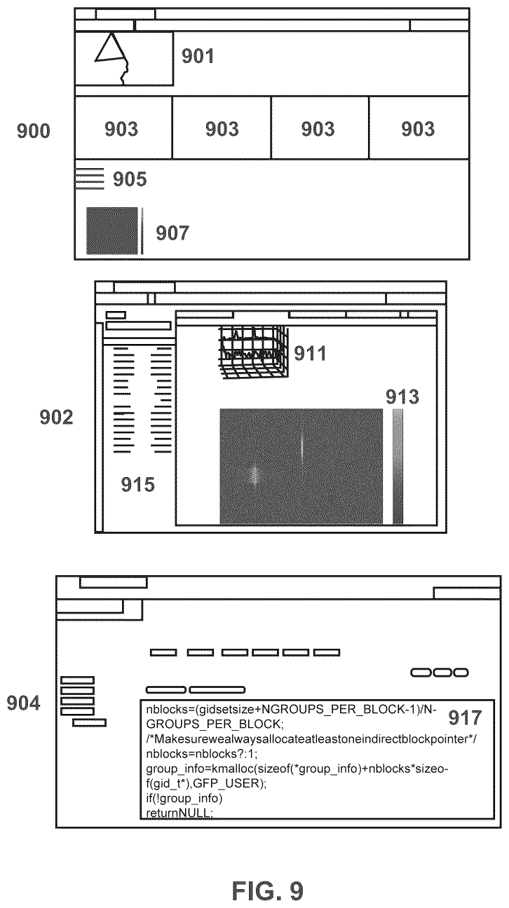

FIG. 9 illustrates example views 900, 902, and 904 of a user interface that may be presented to a user to facilitate interaction with system 10 (FIG. 1). View 900 comprises one or more example fields 901 configured to allow a user to enter and/or select inputs that may be provided to system 10; one or more status windows 903 that provide status updates associated with various tasks related to digital twin generation, simulated environment generation and/or adjustment, etc.; one or more fields 905 associated with observations (e.g., made as described above), calculations, measurements, etc.; and one or more fields 907 associated with external data and/or other information that may be provided to system 10. Note that these are just several possible example fields, windows, etc., View 902 comprise post processing and analysis fields 911, 913, 915 configured to convey information related to the various observations (e.g., made as described above), calculations, measurements, etc., View 904 comprises a view 917 of information in a database (e.g. as described above) that may be included in and/or otherwise accessed by system 10 (e.g., which may be used for generating and/or evaluating a digital twin, and/or used for other purposes). Note that these are just several possible example views, fields, windows, etc.,

Returning to FIG. 1, it should be noted that in some embodiments, engine 12 may be configured such that in the above mentioned operations of controller 14, and input from users and/or sources of information inside or outside system 10, may be processed by controller 14 through a variety of formats, including clicks, touches, uploads, downloads, etc., The illustrated components (e.g., controller 14, API server 26, web server 28, data store 30, and cache server 32) of engine 12 are depicted as discrete functional blocks, but embodiments are not limited to systems in which the functionality described herein is organized as illustrated by FIG. 1. The functionality provided by each of the components of engine 12 may be provided by software or hardware modules that are differently organized than is presently depicted, for example such software or hardware may be intermingled, broken up, distributed (e.g. within a data center or geographically), or otherwise differently organized (e.g., see the examples shown in FIG. 2, 7, 8, etc.). The functionality described herein may be provided by one or more processors of one or more computers executing code stored on a tangible, non-transitory, machine readable medium.

FIG. 10 is a diagram that illustrates an exemplary computer system 1000 in accordance with embodiments of the present system. Various portions of systems and methods described herein may include or be executed on one or more computer systems the same as or similar to computer system 1000. For example, engine 12, mobile user device 34, mobile user device 36, desktop user device 38, external resources 46 and/or other components of system 10 (FIG. 1) may be and/or include one more computer systems the same as or similar to computer system 1000. Further, processes, modules, processor components, and/or other components of system 10 described herein may be executed by one or more processing systems similar to and/or the same as that of computer system 1000.

Computer system 1000 may include one or more processors (e.g., processors 1010a-1010n) coupled to system memory 1020, an input/output I/O device interface 1030, and a network interface 1040 via an input/output (I/O) interface 1050. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computer system 1000. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1020). Computer system 1000 may be a uni-processor system including one processor (e.g., processor 1010a), or a multi-processor system including any number of suitable processors (e.g., 1010a-1010n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus can also be implemented as, special purpose logic circuitry, e.g., an FPGA (field programmable gate array) or an ASIC (application specific integrated circuit). Computer system 1000 may include a plurality of computing devices (e.g., distributed computer systems) to implement various processing functions.

I/O device interface 1030 may provide an interface for connection of one or more I/O devices 1060 to computer system 1000. I/O devices may include devices that receive input (e.g., from a user) or output information (e.g., to a user). I/O devices 1060 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices 1060 may be connected to computer system 1000 through a wired or wireless connection. I/O devices 1060 may be connected to computer system 1000 from a remote location. I/O devices 1060 located on a remote computer system, for example, may be connected to computer system 1000 via a network N and network interface 1040.

Network interface 1040 may include a network adapter that provides for connection of computer system 1000 to network N. Network interface May 1040 may facilitate data exchange between computer system 1000 and other devices connected to the network. Network interface 1040 may support wired or wireless communication. The network may include an electronic communication network, such as the Internet, a local area network (LAN), a wide area network (WAN), a cellular communications network, or the like.

System memory 1020 may be configured to store program instructions 1070 or data 1080. Program instructions 1070 may be executable by a processor (e.g., one or more of processors 1010a-1010n) to implement one or more embodiments of the present techniques. Instructions 1070 may include modules and/or components (e.g., components 16, 18, and/or 20 shown in FIG. 1) of computer program instructions for implementing one or more techniques described herein with regard to various processing modules and/or components. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1020 may include a tangible program carrier having program instructions stored thereon. A tangible program carrier may include a non-transitory computer readable storage medium. A non-transitory computer readable storage medium may include a machine readable storage device, a machine readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random access memory (SRAM), synchronous dynamic RAM (SDRAM)), bulk storage memory (e.g., CD-ROM and/or DVD-ROM, hard-drives), or the like. System memory 1020 may include a non-transitory computer readable storage medium that may have program instructions stored thereon that are executable by a computer processor (e.g., one or more of processors 1010a-1010n) to cause the subject matter and the functional operations described herein. A memory (e.g., system memory 1020) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times, e.g., a copy may be created by writing program code to a first-in-first-out buffer in a network interface, where some of the instructions are pushed out of the buffer before other portions of the instructions are written to the buffer, with all of the instructions residing in memory on the buffer, just not all at the same time.

I/O interface 1050 may be configured to coordinate I/O traffic between processors 1010a-1010n, system memory 1020, network interface 1040, I/O devices 1060, and/or other peripheral devices. I/O interface 1050 may perform protocol, timing, or other data transformations to convert data signals from one component (e.g., system memory 1020) into a format suitable for use by another component (e.g., processors 1010a-1010n). I/O interface 1050 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computer system 1000 or multiple computer systems 1000 configured to host different portions or instances of embodiments. Multiple computer systems 1000 may provide for parallel or sequential processing/execution of one or more portions of the techniques described herein.

Those skilled in the art will appreciate that computer system 1000 is merely illustrative and is not intended to limit the scope of the techniques described herein. Computer system 1000 may include any combination of devices or software that may perform or otherwise provide for the performance of the techniques described herein. For example, computer system 1000 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, a television or device connected to a television (e.g., Apple TV™), or a Global Positioning System (GPS), or the like. Computer system 1000 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system 1000 may be transmitted to computer system 1000 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present invention may be practiced with other computer system configurations.

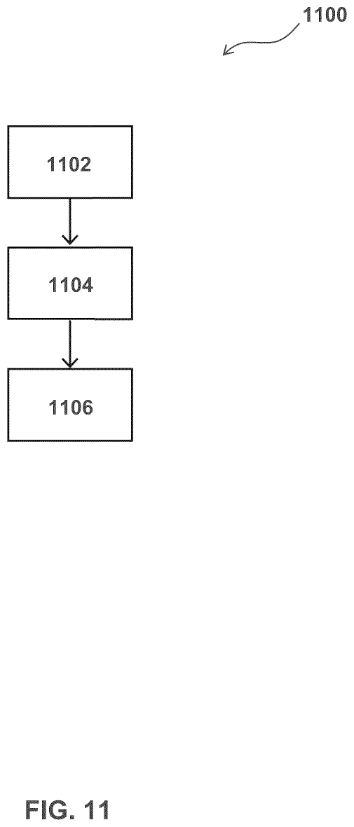

FIG. 11 is a flowchart of a method 1100 for digital model and/or digital twin generation using generative transformer networks and large language models. Method 1100 may be performed with some embodiments of system 10 (FIG. 1), computer system 1000 (FIG. 10), and/or other components discussed above. Method 1100 may include additional operations that are not described, and/or may not include one or more of the operations described below. The operations of method 1100 may be performed in any order that facilitates digital model and/or digital twin generation using generative transformer networks and large language models, as described herein.

Method 1100 begins with operation 1102, comprising defining, with one or more processors, a set of abstract classes associated with various physical systems and/or components of the various physical systems. An abstract class defines general base characteristics of the various physical systems, their components, and/or implementation of the various physical systems and/or their components in the simulated real world conditions. A physical system may comprise a rocket, radar, an aircraft, a vehicle, a sensor, and/or other physical systems, for example. The simulated real world conditions in the digital environment may comprise a physics based model of the simulated real world conditions in the digital environment.

Method 1100 continues with operation 1104, comprising receiving, with a trained parameterized model executed by the one or more processors, user input specifying the real world conditions, the physical system for which the digital twin is generated, one or more modeled components of the physical system, characteristics of the physical system, characteristics of the one or more modeled components, and/or how the physical system and/or the one or more modeled components are to be implemented in the simulated real world conditions. The trained parameterized model is configured to receive multi modal user inputs from the user. In some embodiments, the multi modal user inputs comprise at least two different input modality types. The multi modal user inputs comprising the at least two different input modality types may include two or more of text, image, video, audio, and electromagnetic inputs. In some embodiments, the electromagnetic inputs comprise radiofrequency (RF) waves, light waves, and/or infrared radiation, for example. In some embodiments, the multi modal inputs include a first input comprising text, an image, a video, audio input, or an electromagnetic input, and a second input comprising a different one of the text, image, video, audio input, or electromagnetic input.

In some embodiments, the trained parameterized model comprises a large language model. In some embodiments, the trained parameterized model comprises a generative transformer.

In some embodiments, operation 1104 comprises receiving, with the one or more processors, user input and/or sensor output signals specifying real world conditions for simulation in a virtual world digital environment. Operation 1104 may also include receiving additional user input and/or sensor output signals indicating presence of a real object in the real world. The real object may be part of or related to a physical system for which a digital is generated and/or other objects in the real world.

Operation 1106 comprises determining, with the trained parameterized model, an abstract class and/or classes for the physical system and/or the one or more modeled components based on the user input; and generating code with the trained parameterized model, starting from a determined abstract class and/or classes, and based on the user input, to define and customize the digital twin of the physical system for electronic testing with simulated real world conditions in the digital environment. The code may be Python code, for example.

In some embodiments, operation 1106 comprises executing, with the one or more processors, a model-view-controller framework. The model-view-controller framework comprises an application programming interface (API) configured to define: interactions between the components, the various physical systems, and/or the simulated real world conditions in the digital environment; positions of the components and/or the various physical systems in the digital environment; a state of the components, the various physical systems, and/or the simulated real world conditions in the digital environment; and/or movement of the components and/or the various physical systems through the digital environment. The model view controller framework comprises a user interface configured to generate a multidimensional representation of the components and/or the various physical systems for a visualization by a user; and a controller configured to control the interactions, positions, state, and movement of the components and/or the physical system in the simulated real world conditions in the digital environment over time. The trained parameterized model is configured to generate the code for use by the API, the user interface, and the controller for customizing the electronic testing of the digital twin with the simulated real world conditions in the digital environment according to the user input.

In some embodiments, the digital twin, and/or the electronic testing of the digital twin with the simulated real world conditions in the digital environment, comprises multiple levels of abstraction. A level of abstraction is configured to be entered and/or selected by the user via a user interface, for example. The multiple levels of abstraction may be associated with different time scales such as years, months, weeks, days, hours, minutes, seconds, milliseconds, femtoseconds, etc..

In some embodiments, the digital twin, and/or the electronic testing of the digital twin with the simulated real world conditions in the digital environment, are configured to be automatically adjusted based on received actual data from the real world, and/or other information. Automatically adjusting comprises comparing, with the one or more processors and/or the trained parameterized model, data from the digital twin and/or the electronic testing of the digital twin with the simulated real world conditions in the digital environment to the received actual data from the physical world, and adjusting the code for the digital twin and/or code associated with the simulated real world conditions in the digital environment such that data from the electronic testing of the digital twin with the simulated real world conditions in the digital environment more closely matches the received actual data from the real world. In some embodiments, adjusting the code for the digital twin and/or the code associated with the simulated real world conditions in the digital environment comprises changing, with the one or more processors and/or the trained parameterized model, a parameter of the digital twin and/or the simulated real world conditions in the digital environment. In some embodiments, the trained parameterized model is further configured to be automatically adjusted, by the one or more processors, to improve accuracy of the one or more modeled components in the simulated real world conditions over time, and/or for other purposes.

In some embodiments, operation 1106 includes generating the virtual world digital environment and simulating the real world conditions in the virtual world digital environment based on the user input and/or sensor output signals; determining characteristics of the real object based on the user input and/or sensor output signals; and generating a photo realistic representation of the real object in simulated real world conditions in the virtual world digital environment. Generating the photo realistic representation may be based on the user input and/or sensor output signals and the characteristics of the real object, and/or other information. The photo realistic representation is configured to accurately reflect the characteristics of the real object such that the photo realistic representation interacts with the simulated real world conditions in the virtual world digital environment as the real object interacts with the real world conditions. Generating the photo realistic representation of the real object in the simulated real world conditions comprises implementing a simulation of the real object in the simulated real world conditions. The real world conditions comprise atmospheric weather related conditions, presence of other moving or stationary objects, presence of radiofrequency (RF) waves, presence of light waves, presence of infrared radiation, presence of environmental noise, and/or other conditions.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may provided by sending instructions to retrieve that information from a content delivery network.

The reader should appreciate that the present application describes several inventions. Rather than separating those inventions into multiple isolated patent applications, applicants have grouped these inventions into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to cost constraints, some inventions disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such inventions or all aspects of such inventions.

It should be understood that the description and the drawings are not intended to limit the invention to the particular form disclosed, but to the contrary, the intention is to cover all modifications, equivalents, and alternatives falling within the spirit and scope of the present invention as defined by the appended claims. Further modifications and alternative embodiments of various aspects of the invention will be apparent to those skilled in the art in view of this description. Accordingly, this description and the drawings are to be construed as illustrative only and are for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed or omitted, and certain features of the invention may be utilized independently, all as would be apparent to one skilled in the art after having the benefit of this description of the invention. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X′ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The present techniques will be better understood with reference to the following enumerated embodiments, which may be used alone and/or in any combination:
1. A non-transitory computer readable medium having instructions thereon, the instructions, when executed by a computer, causing the computer to execute a digital twin generator, the digital twin generator configured to generate a digital twin of a physical system useable for electronic testing with simulated real world conditions in a digital environment, the digital twin generator comprising: a set of abstract classes associated with various physical systems and/or components of the various physical systems, an abstract class defining general base characteristics of the various physical systems, their components, and/or implementation of the various physical systems and/or their components in the simulated real world conditions; and a trained parameterized model configured to: receive user input specifying the real world conditions, the physical system for which the digital twin is generated, one or more modeled components of the physical system, characteristics of the physical system, characteristics of the one or more modeled components, and/or how the physical system and/or the one or more modeled components are to be implemented in the simulated real world conditions; determine an abstract class and/or classes for the physical system and/or the one or more modeled components based on the user input; and generate code, starting from a determined abstract class and/or classes, and based on the user input, to define and customize the digital twin of the physical system for electronic testing with simulated real world conditions in the digital environment.
2. The medium of embodiment 1, wherein the trained parameterized model comprises a large language model.
3. The medium of any of the previous embodiments, wherein the trained parameterized model comprises a generative transformer.
4. The medium of any of the previous embodiments, wherein the physical system comprises a rocket, radar, an aircraft, a vehicle, and/or a sensor.
5. The medium of any of the previous embodiments, the digital twin generator further comprising a model-view-controller framework, the model-view-controller framework comprising: an application programming interface (API) configured to define: interactions between the components, the various physical systems, and/or the simulated real world conditions in the digital environment; positions of the components and/or the various physical systems in the digital environment; a state of the components, the various physical systems, and/or the simulated real world conditions in the digital environment; and/or movement of the components and/or the various physical systems through the digital environment; a user interface configured to generate a multidimensional representation of the components and/or the various physical systems for a visualization by a user; and a controller configured to control the interactions, positions, state, and movement of the components and/or the physical system in the simulated real world conditions in the digital environment over time; wherein the trained parameterized model is configured to generate the code for use by the API, the user interface, and the controller for customizing the electronic testing of the digital twin with the simulated real world conditions in the digital environment according to the user input.
6. The medium of any of the previous embodiments, wherein the digital twin, and/or the electronic testing of the digital twin with the simulated real world conditions in the digital environment, comprises multiple levels of abstraction.
7. The medium of any of the previous embodiments, wherein a level of abstraction is configured to be entered and/or selected by the user via a user interface.
8. The medium of any of the previous embodiments, wherein the multiple levels of abstraction are associated with different time scales, and wherein a time scale is measured in years, months, weeks, days, hours, minutes, seconds, milliseconds, or femtoseconds.
9. The medium of any of the previous embodiments, wherein the physical system is a quantum radar system and a level of abstraction of the electronic testing of a digital twin of the quantum radar system is on a femtosecond time scale.
10. The medium of any of the previous embodiments, wherein the digital twin, and/or the electronic testing of the digital twin with the simulated real world conditions in the digital environment, are configured to be automatically adjusted based on received actual data from the real world.
11. The medium of any of the previous embodiments, wherein automatically adjusting comprises comparing data from the digital twin and/or the electronic testing of the digital twin with the simulated real world conditions in the digital environment to the received actual data from the physical world, and adjusting the code for the digital twin and/or code associated with the simulated real world conditions in the digital environment such that data from the electronic testing of the digital twin with the simulated real world conditions in the digital environment more closely matches the received actual data from the real world.
12. The medium of any of the previous embodiments, wherein adjusting the code for the digital twin and/or the code associated with the simulated real world conditions in the digital environment comprises changing a parameter of the digital twin and/or the simulated real world conditions in the digital environment.
13. The medium of any of the previous embodiments, wherein the simulated real world conditions in the digital environment comprise a physics based model of the simulated real world conditions in the digital environment.
14. The medium of any of the previous embodiments, wherein the trained parameterized model is further configured to be automatically adjusted to improve accuracy of the one or more modeled components in the simulated real world conditions over time.
15. The medium of any of the previous embodiments, wherein the trained parameterized model is configured to receive multi modal user inputs from the user.
16. The medium of any of the previous embodiments, wherein the multi modal user inputs comprise at least two different input modality types.
17. The medium of any of the previous embodiments, wherein the multi modal user inputs comprising the at least two different input modality types include two or more of text, image, video, audio, and electromagnetic inputs.
18. The medium of any of the previous embodiments, wherein the electromagnetic inputs comprise radiofrequency (RF) waves, light waves, and/or infrared radiation.
19. The medium of any of the previous embodiments, wherein the multi modal using inputs comprising the at least two different input modality types include a first input comprising text, an image, a video, audio input, or an electromagnetic input, and a second input comprising a different one of the text, image, video, audio input, or electromagnetic input.
20. The medium of any of the previous embodiments, wherein the digital twin comprises an electronic model of the physical system, and the code comprises Python code.
21. A non-transitory computer readable medium having instructions thereon, the instructions, when executed by a computer, causing the computer to represent real world objects accurately in a virtual world digital environment, the instructions causing the computer to: receive first user input and/or sensor output signals specifying real world conditions for simulation in the virtual world digital environment; receive second user input and/or sensor output signals indicating presence of a real object in the real world; and execute a trained parameterized model configured to: generate the virtual world digital environment and simulate the real world conditions in the virtual world digital environment based on the first user input and/or sensor output signals; determine characteristics of the real object based on the second user input and/or sensor output signals; and generate a photo realistic representation of the real object in simulated real world conditions in the virtual world digital environment based on the second user input and/or sensor output signals and the characteristics of the real object, the photo realistic representation accurately reflecting the characteristics of the real object such that the photo realistic representation interacts with the simulated real world conditions in the virtual world digital environment as the real object interacts with the real world conditions.
22. The medium of any of the previous embodiments, wherein generating the photo realistic representation of the real object in the simulated real world conditions comprises implementing a simulation of the real object in the simulated real world conditions.
23. The medium of any of the previous embodiments, the real world conditions comprising atmospheric weather related conditions, presence of other moving or stationary objects, presence of radiofrequency (RF) waves, presence of light waves, presence of infrared radiation, presence of environmental noise.
24. The medium of any of the previous embodiments, wherein the real object comprises a rocket, radar, an aircraft, a vehicle, and/or a sensor.
25. The medium of any of the previous embodiments, wherein the simulated real world conditions in the virtual world digital environment comprise a physics based model of the simulated real world conditions in the virtual world digital environment.
26. The medium of any of the previous embodiments, wherein the trained parameterized model comprises a large language model.
27. The medium of any of the previous embodiments, wherein the trained parameterized model comprises a generative transformer.
28. The medium of any of the previous embodiments, wherein the photo realistic representation comprises a digital twin generated by a digital twin generator, the digital twin generator comprising: a set of abstract classes associated with various physical systems and/or components of the various physical systems, an abstract class defining general base characteristics of the various physical systems, their components, and/or implementation of the various physical systems and/or their components in the simulated real world conditions; the trained parameterized model, the trained parameterized model further configured to: determine an abstract class and/or classes for the real object based on the user input and/or the characteristics; and generate code, starting from a determined abstract class and/or classes, and based on the user input and/or the characteristics, to define and customize the digital twin of the real object for simulation in the real world conditions in the virtual world digital environment; a model-view-controller framework, the model-view-controller framework comprising: an application programming interface (API) configured to define: interactions between the digital twin and the simulated real world conditions in the virtual world digital environment; positions of the digital twin in the virtual world digital environment; a state of the digital twin and/or the simulated real world conditions in the virtual world digital environment; and/or movement of the digital twin through the virtual world digital environment; a user interface configured to generate a multidimensional representation of the digital twin in the virtual world digital environment for a visualization by a user; and a controller configured to control the interactions, positions, state, and movement of the digital twin in the simulated real world conditions in the virtual world digital environment over time; wherein the trained parameterized model is configured to generate the code for use by the API, the user interface, and the controller for customizing the digital twin with the simulated real world conditions in the virtual world digital environment according to the user input.
29. The medium of any of the previous embodiments, wherein the trained parameterized model is configured to receive multi modal user inputs.
30. The medium of any of the previous embodiments, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.
31. A non-transitory computer readable medium having instructions thereon, the instructions, when executed by a computer, causing the computer to update a digital environment based on real world conditions, the instructions causing the computer to: receive user and/or sensor input specifying the real world conditions; and execute a trained parameterized model to: generate code, based on the user and/or sensor input, to define and customize a digital environment to simulate the real world conditions; and automatically adjust simulated real world conditions in the digital environment based on additionally received actual data from the real world, wherein automatically adjusting comprises comparing data from the simulated real world conditions in the digital environment to the additionally received actual data from the real world, and adjusting the code for the simulated real world conditions in the digital environment such that data from the simulated real world conditions in the digital environment more closely matches the additionally received actual data from the real world.
32. The medium of any of the previous embodiments, wherein adjusting the code comprises changing a parameter of the simulated real world conditions in the digital environment.
33. The medium of any of the previous embodiments, wherein the trained parameterized model comprises a large language model.
34. The medium of any of the previous embodiments, wherein the trained parameterized model comprises a generative transformer.
35. The medium of any of the previous embodiments, wherein the simulated real world conditions in the digital environment comprise multiple levels of abstraction.
36. The medium of any of the previous embodiments, wherein the multiple levels of abstraction are associated with different time scales, and wherein a time scale is measured in years, months, weeks, days, hours, minutes, seconds, milliseconds, or femtoseconds.
37. The medium of any of the previous embodiments, wherein the simulated real world conditions in the digital environment comprise a physics based model of the simulated real world conditions in the digital environment.
38. The medium of any of the previous embodiments, wherein the trained parameterized model is configured to receive multi modal user inputs.
39. The medium of any of the previous embodiments, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.
40. The medium of any of the previous embodiments, wherein the code comprises Python code.
41. A method for generating a digital twin of a physical system useable for electronic testing with simulated real world conditions in a digital environment, the method comprising: defining, with one or more processors, a set of abstract classes associated with various physical systems and/or components of the various physical systems, an abstract class defining general base characteristics of the various physical systems, their components, and/or implementation of the various physical systems and/or their components in the simulated real world conditions; receiving, with a trained parameterized model executed by the one or more processors, user input specifying the real world conditions, the physical system for which the digital twin is generated, one or more modeled components of the physical system, characteristics of the physical system, characteristics of the one or more modeled components, and/or how the physical system and/or the one or more modeled components are to be implemented in the simulated real world conditions; determining, with the trained parameterized model, an abstract class and/or classes for the physical system and/or the one or more modeled components based on the user input; and generating code with the trained parameterized model, starting from a determined abstract class and/or classes, and based on the user input, to define and customize the digital twin of the physical system for electronic testing with simulated real world conditions in the digital environment.
42. The method of embodiment 41, wherein the trained parameterized model comprises a large language model.
43. The method of any of the previous embodiments, wherein the trained parameterized model comprises a generative transformer.
44. The method of any of the previous embodiments, wherein the physical system comprises a rocket, radar, an aircraft, a vehicle, and/or a sensor.
45. The method of any of the previous embodiments, further comprising executing, with the one or more processors, a model-view-controller framework, the model-view-controller framework comprising: an application programming interface (API) configured to define: interactions between the components, the various physical systems, and/or the simulated real world conditions in the digital environment; positions of the components and/or the various physical systems in the digital environment; a state of the components, the various physical systems, and/or the simulated real world conditions in the digital environment; and/or movement of the components and/or the various physical systems through the digital environment; a user interface configured to generate a multidimensional representation of the components and/or the various physical systems for a visualization by a user; and a controller configured to control the interactions, positions, state, and movement of the components and/or the physical system in the simulated real world conditions in the digital environment over time; wherein the trained parameterized model is configured to generate the code for use by the API, the user interface, and the controller for customizing the electronic testing of the digital twin with the simulated real world conditions in the digital environment according to the user input.
46. The method of any of the previous embodiments, wherein the digital twin, and/or the electronic testing of the digital twin with the simulated real world conditions in the digital environment, comprises multiple levels of abstraction.
47. The method of any of the previous embodiments, wherein a level of abstraction is configured to be entered and/or selected by the user via a user interface.
48. The method of any of the previous embodiments, wherein the multiple levels of abstraction are associated with different time scales, and wherein a time scale is measured in years, months, weeks, days, hours, minutes, seconds, milliseconds, or femtoseconds.
49. The method of any of the previous embodiments, wherein the physical system is a quantum radar system and a level of abstraction of the electronic testing of a digital twin of the quantum radar system is on a femtosecond time scale.
50. The method of any of the previous embodiments, wherein the digital twin, and/or the electronic testing of the digital twin with the simulated real world conditions in the digital environment, are configured to be automatically adjusted based on received actual data from the real world.
51. The method of any of the previous embodiments, wherein automatically adjusting comprises comparing, with the one or more processors and/or the trained parameterized model, data from the digital twin and/or the electronic testing of the digital twin with the simulated real world conditions in the digital environment to the received actual data from the physical world, and adjusting the code for the digital twin and/or code associated with the simulated real world conditions in the digital environment such that data from the electronic testing of the digital twin with the simulated real world conditions in the digital environment more closely matches the received actual data from the real world.
52. The method of any of the previous embodiments, wherein adjusting the code for the digital twin and/or the code associated with the simulated real world conditions in the digital environment comprises changing, with the one or more processors and/or the trained parameterized model, a parameter of the digital twin and/or the simulated real world conditions in the digital environment.
53. The method of any of the previous embodiments, wherein the simulated real world conditions in the digital environment comprise a physics based model of the simulated real world conditions in the digital environment.
54. The method of any of the previous embodiments, wherein the trained parameterized model is further configured to be automatically adjusted, by the one or more processors, to improve accuracy of the one or more modeled components in the simulated real world conditions over time.
55. The method of any of the previous embodiments, wherein the trained parameterized model is configured to receive multi modal user inputs from the user.
56. The method of any of the previous embodiments, wherein the multi modal user inputs comprise at least two different input modality types.
57. The method of any of the previous embodiments, wherein the multi modal user inputs comprising the at least two different input modality types include two or more of text, image, video, audio, and electromagnetic inputs.
58. The method of any of the previous embodiments, wherein the electromagnetic inputs comprise radiofrequency (RF) waves, light waves, and/or infrared radiation.
59. The method of any of the previous embodiments, wherein the multi modal using inputs comprising the at least two different input modality types include a first input comprising text, an image, a video, audio input, or an electromagnetic input, and a second input comprising a different one of the text, image, video, audio input, or electromagnetic input.
60. The method of any of the previous embodiments, wherein the digital twin comprises an electronic model of the physical system, and the code comprises Python code.
61. A method for representing real world objects accurately in a virtual world digital environment, the method comprising: receiving, with one or more processors, first user input and/or sensor output signals specifying real world conditions for simulation in the virtual world digital environment; receiving, with the one or more processors, second user input and/or sensor output signals indicating presence of a real object in the real world; executing, with the one or more processors, a trained parameterized model configured to: generate the virtual world digital environment and simulate the real world conditions in the virtual world digital environment based on the first user input and/or sensor output signals; determine characteristics of the real object based on the second user input and/or sensor output signals; and generate a photo realistic representation of the real object in simulated real world conditions in the virtual world digital environment based on the second user input and/or sensor output signals and the characteristics of the real object, the photo realistic representation accurately reflecting the characteristics of the real object such that the photo realistic representation interacts with the simulated real world conditions in the virtual world digital environment as the real object interacts with the real world conditions.
62. The method of any of the previous embodiments, wherein generating the photo realistic representation of the real object in the simulated real world conditions comprises implementing a simulation of the real object in the simulated real world conditions.
63. The method of any of the previous embodiments, the real world conditions comprising atmospheric weather related conditions, presence of other moving or stationary objects, presence of radiofrequency (RF) waves, presence of light waves, presence of infrared radiation, presence of environmental noise.
64. The method of any of the previous embodiments, wherein the real object comprises a rocket, radar, an aircraft, a vehicle, and/or a sensor.
65. The method of any of the previous embodiments, wherein the simulated real world conditions in the virtual world digital environment comprise a physics based model of the simulated real world conditions in the virtual world digital environment.
66. The method of any of the previous embodiments, wherein the trained parameterized model comprises a large language model.
67. The method of any of the previous embodiments, wherein the trained parameterized model comprises a generative transformer.
68. The method of any of the previous embodiments, wherein the photo realistic representation comprises a digital twin generated by a digital twin generator, the digital twin generator executed by the one or more processors and comprising: a set of abstract classes associated with various physical systems and/or components of the various physical systems, an abstract class defining general base characteristics of the various physical systems, their components, and/or implementation of the various physical systems and/or their components in the simulated real world conditions; the trained parameterized model, the trained parameterized model further configured to: determine an abstract class and/or classes for the real object based on the user input and/or the characteristics; and generate code, starting from a determined abstract class and/or classes, and based on the user input and/or the characteristics, to define and customize the digital twin of the real object for simulation in the real world conditions in the virtual world digital environment; a model-view-controller framework, the model-view-controller framework comprising: an application programming interface (API) configured to define: interactions between the digital twin and the simulated real world conditions in the virtual world digital environment; positions of the digital twin in the virtual world digital environment; a state of the digital twin and/or the simulated real world conditions in the virtual world digital environment; and/or movement of the digital twin through the virtual world digital environment; a user interface configured to generate a multidimensional representation of the digital twin in the virtual world digital environment for a visualization by a user; and a controller configured to control the interactions, positions, state, and movement of the digital twin in the simulated real world conditions in the virtual world digital environment over time; wherein the trained parameterized model is configured to generate the code for use by the API, the user interface, and the controller for customizing the digital twin with the simulated real world conditions in the virtual world digital environment according to the user input.
69. The method of any of the previous embodiments, wherein the trained parameterized model is configured to receive multi modal user inputs.
70. The method of any of the previous embodiments, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.
71. A method for updating a digital environment based on real world conditions, the method comprising: receiving, with one or more processors, user and/or sensor input specifying the real world conditions; and executing, with the one or more processors, a trained parameterized model to: generate code, based on the user and/or sensor input, to define and customize a digital environment to simulate the real world conditions; and automatically adjust simulated real world conditions in the digital environment based on additionally received actual data from the real world, wherein automatically adjusting comprises comparing data from the simulated real world conditions in the digital environment to the additionally received actual data from the real world, and adjusting the code for the simulated real world conditions in the digital environment such that data from the simulated real world conditions in the digital environment more closely matches the additionally received actual data from the real world.
72. The method of any of the previous embodiments, wherein adjusting the code comprises changing a parameter of the simulated real world conditions in the digital environment.
73. The method of any of the previous embodiments, wherein the trained parameterized model comprises a large language model.
74. The method of any of the previous embodiments, wherein the trained parameterized model comprises a generative transformer.
75. The method of any of the previous embodiments, wherein the simulated real world conditions in the digital environment comprise multiple levels of abstraction.
76. The method of any of the previous embodiments, wherein the multiple levels of abstraction are associated with different time scales, and wherein a time scale is measured in years, months, weeks, days, hours, minutes, seconds, milliseconds, or femtoseconds.
77. The method of any of the previous embodiments, wherein the simulated real world conditions in the digital environment comprise a physics based model of the simulated real world conditions in the digital environment.
78. The method of any of the previous embodiments, wherein the trained parameterized model is configured to receive multi modal user inputs.
79. The method of any of the previous embodiments, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.
80. The method of any of the previous embodiments, wherein the code comprises Python code.

What is claimed is:

1. A non-transitory computer readable medium having instructions thereon, the instructions, when executed by a computer, causing the computer to execute a digital twin generator, the digital twin generator configured to generate a digital twin of a physical system useable for electronic testing with simulated real world conditions in a digital environment, the digital twin generator comprising:
a set of abstract classes associated with various physical systems and/or components of the various physical systems, an abstract class defining general base characteristics of the various physical systems, their components, and/or implementation of the various physical systems and/or their components in the simulated real world conditions; and
a trained parameterized model configured to:
receive user input specifying the real world conditions, the physical system for which the digital twin is generated, one or more modeled components of the physical system, characteristics of the physical system, characteristics of the one or more modeled components, and/or how the physical system and/or the one or more modeled components are to be implemented in the simulated real world conditions;
determine an abstract class and/or classes for the physical system and/or the one or more modeled components based on the user input; and
generate code, starting from a determined abstract class and/or classes, and based on the user input, to define and customize the digital twin of the physical system for electronic testing with simulated real world conditions in the digital environment.

2. The medium of claim 1, wherein the trained parameterized model comprises a large language model.

3. The medium of claim 1, wherein the trained parameterized model comprises a generative transformer.

4. The medium of claim 1, wherein the physical system comprises a rocket, radar, an aircraft, a vehicle, and/or a sensor.

5. The medium of claim 1, the digital twin generator further comprising a model-view-controller framework, the model-view-controller framework comprising:
an application programming interface (API) configured to define:
interactions between the components, the various physical systems, and/or the simulated real world conditions in the digital environment;
positions of the components and/or the various physical systems in the digital environment;
a state of the components, the various physical systems, and/or the simulated real world conditions in the digital environment; and/or
movement of the components and/or the various physical systems through the digital environment;
a user interface configured to generate a multidimensional representation of the components and/or the various physical systems for a visualization by a user; and
a controller configured to control the interactions, positions, state, and movement of the components and/or the physical system in the simulated real world conditions in the digital environment over time;
wherein the trained parameterized model is configured to generate the code for use by the API, the user interface, and the controller for customizing the electronic testing of the digital twin with the simulated real world conditions in the digital environment according to the user input.

6. The medium of claim 1, wherein the digital twin, and/or the electronic testing of the digital twin with the simulated real world conditions in the digital environment, comprises multiple levels of abstraction.

7. The medium of claim 6, wherein a level of abstraction is configured to be entered and/or selected by the user via a user interface.

8. The medium of claim 6, wherein the multiple levels of abstraction are associated with different time scales, and wherein a time scale is measured in years, months, weeks, days, hours, minutes, seconds, milliseconds, or femtoseconds.

9. The medium of claim 8, wherein the physical system is a quantum radar system and a level of abstraction of the electronic testing of a digital twin of the quantum radar system is on a femtosecond time scale.

10. The medium of claim 1, wherein the digital twin, and/or the electronic testing of the digital twin with the simulated real world conditions in the digital environment, are configured to be automatically adjusted based on received actual data from the real world.

11. The medium of claim 10, wherein automatically adjusting comprises comparing data from the digital twin and/or the electronic testing of the digital twin with the simulated real world conditions in the digital environment to the received actual data from the physical world, and adjusting the code for the digital twin and/or code associated with the simulated real world conditions in the digital environment such that data from the electronic testing of the digital twin with the simulated real world conditions in the digital environment more closely matches the received actual data from the real world.

12. The medium of claim 11, wherein adjusting the code for the digital twin and/or the code associated with the simulated real world conditions in the digital environment comprises changing a parameter of the digital twin and/or the simulated real world conditions in the digital environment.

13. The medium of claim 12, wherein the simulated real world conditions in the digital environment comprise a physics based model of the simulated real world conditions in the digital environment.

14. The medium of claim 10, wherein the trained parameterized model is further configured to be automatically adjusted to improve accuracy of the one or more modeled components in the simulated real world conditions over time.

15. The medium of claim 1, wherein the trained parameterized model is configured to receive multi modal user inputs from the user.

16. The medium of claim 15, wherein the multi modal user inputs comprise at least two different input modality types.

17. The medium of claim 16, wherein the multi modal user inputs comprising the at least two different input modality types include two or more of text, image, video, audio, and electromagnetic inputs.

18. The medium of claim 17, wherein the electromagnetic inputs comprise radiofrequency (RF) waves, light waves, and/or infrared radiation.

19. The medium of claim 16, wherein the multi modal using inputs comprising the at least two different input modality types include a first input comprising text, an image, a video, audio input, or an electromagnetic input, and a second input comprising a different one of the text, image, video, audio input, or electromagnetic input.

20. The medium of claim 1, wherein the digital twin comprises an electronic model of the physical system, and the code comprises Python code.

21. A non-transitory computer readable medium having instructions thereon, the instructions, when executed by a computer, causing the computer to represent real world objects accurately in a virtual world digital environment, the instructions causing the computer to:
receive first user input and/or sensor output signals specifying real world conditions for simulation in the virtual world digital environment;
receive second user input and/or sensor output signals indicating presence of a real object in the real world; and
execute a trained parameterized model configured to:
generate the virtual world digital environment and simulate the real world conditions in the virtual world digital environment based on the first user input and/or sensor output signals;
determine characteristics of the real object based on the second user input and/or sensor output signals; and
generate a photo realistic representation of the real object in simulated real world conditions in the virtual world digital environment based on the second user input and/or sensor output signals and the characteristics of the real object, the photo realistic representation accurately reflecting the characteristics of the real object such that the photo realistic representation interacts with the simulated real world conditions in the virtual world digital environment as the real object interacts with the real world conditions.

22. The medium of claim 21, wherein generating the photo realistic representation of the real object in the simulated real world conditions comprises implementing a simulation of the real object in the simulated real world conditions.

23. The medium of claim 21, the real world conditions comprising atmospheric weather related conditions, presence of other moving or stationary objects, presence of radiofrequency (RF) waves, presence of light waves, presence of infrared radiation, presence of environmental noise.

24. The medium of claim 21, wherein the real object comprises a rocket, radar, an aircraft, a vehicle, and/or a sensor.

25. The medium of claim 21, wherein the simulated real world conditions in the virtual world digital environment comprise a physics based model of the simulated real world conditions in the virtual world digital environment.

26. The medium of claim 21, wherein the trained parameterized model comprises a large language model.

27. The medium of claim 21, wherein the trained parameterized model comprises a generative transformer.

28. The medium of claim 21, wherein the photo realistic representation comprises a digital twin generated by a digital twin generator, the digital twin generator comprising:
a set of abstract classes associated with various physical systems and/or components of the various physical systems, an abstract class defining general base characteristics of the various physical systems, their components, and/or implementation of the various physical systems and/or their components in the simulated real world conditions;
the trained parameterized model, the trained parameterized model further configured to:
determine an abstract class and/or classes for the real object based on the user input and/or the characteristics; and
generate code, starting from a determined abstract class and/or classes, and based on the user input and/or the characteristics, to define and customize the digital twin of the real object for simulation in the real world conditions in the virtual world digital environment;
a model-view-controller framework, the model-view-controller framework comprising:
an application programming interface (API) configured to define:
interactions between the digital twin and the simulated real world conditions in the virtual world digital environment;
positions of the digital twin in the virtual world digital environment;
a state of the digital twin and/or the simulated real world conditions in the virtual world digital environment; and/or
movement of the digital twin through the virtual world digital environment;
a user interface configured to generate a multidimensional representation of the digital twin in the virtual world digital environment for a visualization by a user; and
a controller configured to control the interactions, positions, state, and movement of the digital twin in the simulated real world conditions in the virtual world digital environment over time;
wherein the trained parameterized model is configured to generate the code for use by the API, the user interface, and the controller for customizing the digital twin with the simulated real world conditions in the virtual world digital environment according to the user input.

29. The medium of claim 21, wherein the trained parameterized model is configured to receive multi modal user inputs.

30. The medium of claim 29, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.

31. A non-transitory computer readable medium having instructions thereon, the instructions, when executed by a computer, causing the computer to update a digital environment based on real world conditions, the instructions causing the computer to:
receive user and/or sensor input specifying the real world conditions; and
execute a trained parameterized model to:
generate code, based on the user and/or sensor input, to define and customize a digital environment to simulate the real world conditions; and
automatically adjust simulated real world conditions in the digital environment based on additionally received actual data from the real world, wherein automatically adjusting comprises comparing data from the simulated real world conditions in the digital environment to the additionally received actual data from the real world, and adjusting the code for the simulated real world conditions in the digital environment such that data from the simulated real world conditions in the digital environment more closely matches the additionally received actual data from the real world.

32. The medium of claim 31, wherein adjusting the code comprises changing a parameter of the simulated real world conditions in the digital environment.

33. The medium of claim 31, wherein the trained parameterized model comprises a large language model.

34. The medium of claim 31, wherein the trained parameterized model comprises a generative transformer.

35. The medium of claim 31, wherein the simulated real world conditions in the digital environment comprise multiple levels of abstraction.

36. The medium of claim 35, wherein the multiple levels of abstraction are associated with different time scales, and wherein a time scale is measured in years, months, weeks, days, hours, minutes, seconds, milliseconds, or femtoseconds.

37. The medium of claim 31, wherein the simulated real world conditions in the digital environment comprise a physics based model of the simulated real world conditions in the digital environment.

38. The medium of claim 31, wherein the trained parameterized model is configured to receive multi modal user inputs.

39. The medium of claim 38, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.

40. The medium of claim 31, wherein the code comprises Python code.

41. A method for generating a digital twin of a physical system useable for electronic testing with simulated real world conditions in a digital environment, the method comprising:
defining, with one or more processors, a set of abstract classes associated with various physical systems and/or components of the various physical systems, an abstract class defining general base characteristics of the various physical systems, their components, and/or implementation of the various physical systems and/or their components in the simulated real world conditions;
receiving, with a trained parameterized model executed by the one or more processors, user input specifying the real world conditions, the physical system for which the digital twin is generated, one or more modeled components of the physical system, characteristics of the physical system, characteristics of the one or more modeled components, and/or how the physical system and/or the one or more modeled components are to be implemented in the simulated real world conditions;
determining, with the trained parameterized model, an abstract class and/or classes for the physical system and/or the one or more modeled components based on the user input; and
generating code with the trained parameterized model, starting from a determined abstract class and/or classes, and based on the user input, to define and customize the digital twin of the physical system for electronic testing with simulated real world conditions in the digital environment.

42. The method of claim 41, wherein the trained parameterized model comprises a large language model.

43. The method of claim 41, wherein the trained parameterized model comprises a generative transformer.

44. The method of claim 41, wherein the physical system comprises a rocket, radar, an aircraft, a vehicle, and/or a sensor.

45. The method of claim 41, further comprising executing, with the one or more processors, a model-view-controller framework, the model-view-controller framework comprising:
an application programming interface (API) configured to define:
interactions between the components, the various physical systems, and/or the simulated real world conditions in the digital environment;
positions of the components and/or the various physical systems in the digital environment;
a state of the components, the various physical systems, and/or the simulated real world conditions in the digital environment; and/or
movement of the components and/or the various physical systems through the digital environment;
a user interface configured to generate a multidimensional representation of the components and/or the various physical systems for a visualization by a user; and
a controller configured to control the interactions, positions, state, and movement of the components and/or the physical system in the simulated real world conditions in the digital environment over time;
wherein the trained parameterized model is configured to generate the code for use by the API, the user interface, and the controller for customizing the electronic testing of the digital twin with the simulated real world conditions in the digital environment according to the user input.

46. The method of claim 41, wherein the digital twin, and/or the electronic testing of the digital twin with the simulated real world conditions in the digital environment, comprises multiple levels of abstraction.

47. The method of claim 46, wherein a level of abstraction is configured to be entered and/or selected by the user via a user interface.

48. The method of claim 46, wherein the multiple levels of abstraction are associated with different time scales, and wherein a time scale is measured in years, months, weeks, days, hours, minutes, seconds, milliseconds, or femtoseconds.

49. The method of claim 48, wherein the physical system is a quantum radar system and a level of abstraction of the electronic testing of a digital twin of the quantum radar system is on a femtosecond time scale.

50. The method of claim 41, wherein the digital twin, and/or the electronic testing of the digital twin with the simulated real world conditions in the digital environment, are configured to be automatically adjusted based on received actual data from the real world.

51. The method of claim 50, wherein automatically adjusting comprises comparing, with the one or more processors and/or the trained parameterized model, data from the digital twin and/or the electronic testing of the digital twin with the simulated real world conditions in the digital environment to the received actual data from the physical world, and adjusting the code for the digital twin and/or code associated with the simulated real world conditions in the digital environment such that data from the electronic testing of the digital twin with the simulated real world conditions in the digital environment more closely matches the received actual data from the real world.

52. The method of claim 51, wherein adjusting the code for the digital twin and/or the code associated with the simulated real world conditions in the digital environment comprises changing, with the one or more processors and/or the trained parameterized model, a parameter of the digital twin and/or the simulated real world conditions in the digital environment.

53. The method of claim 52, wherein the simulated real world conditions in the digital environment comprise a physics based model of the simulated real world conditions in the digital environment.

54. The method of claim 50, wherein the trained parameterized model is further configured to be automatically adjusted, by the one or more processors, to improve accuracy of the one or more modeled components in the simulated real world conditions over time.

55. The method of claim 41, wherein the trained parameterized model is configured to receive multi modal user inputs from the user.

56. The method of claim 55, wherein the multi modal user inputs comprise at least two different input modality types.

57. The method of claim 56, wherein the multi modal user inputs comprising the at least two different input modality types include two or more of text, image, video, audio, and electromagnetic inputs.

58. The method of claim 57, wherein the electromagnetic inputs comprise radiofrequency (RF) waves, light waves, and/or infrared radiation.

59. The method of claim 56, wherein the multi modal using inputs comprising the at least two different input modality types include a first input comprising text, an image, a video, audio input, or an electromagnetic input, and a second input comprising a different one of the text, image, video, audio input, or electromagnetic input.

60. The method of claim 41, wherein the digital twin comprises an electronic model of the physical system, and the code comprises Python code.

61. A method for representing real world objects accurately in a virtual world digital environment, the method comprising:
receiving, with one or more processors, first user input and/or sensor output signals specifying real world conditions for simulation in the virtual world digital environment;
receiving, with the one or more processors, second user input and/or sensor output signals indicating presence of a real object in the real world;
executing, with the one or more processors, a trained parameterized model configured to:
generate the virtual world digital environment and simulate the real world conditions in the virtual world digital environment based on the first user input and/or sensor output signals;
determine characteristics of the real object based on the second user input and/or sensor output signals; and
generate a photo realistic representation of the real object in simulated real world conditions in the virtual world digital environment based on the second user input and/or sensor output signals and the characteristics of the real object, the photo realistic representation accurately reflecting the characteristics of the real object such that the photo realistic representation interacts with the simulated real world conditions in the virtual world digital environment as the real object interacts with the real world conditions.

62. The method of claim 61, wherein generating the photo realistic representation of the real object in the simulated real world conditions comprises implementing a simulation of the real object in the simulated real world conditions.

63. The method of claim 61, the real world conditions comprising atmospheric weather related conditions, presence of other moving or stationary objects, presence of radiofrequency (RF) waves, presence of light waves, presence of infrared radiation, presence of environmental noise.

64. The method of claim 61, wherein the real object comprises a rocket, radar, an aircraft, a vehicle, and/or a sensor.

65. The method of claim 61, wherein the simulated real world conditions in the virtual world digital environment comprise a physics based model of the simulated real world conditions in the virtual world digital environment.

66. The method of claim 61, wherein the trained parameterized model comprises a large language model.

67. The method of claim 61, wherein the trained parameterized model comprises a generative transformer.

68. The method of claim 61, wherein the photo realistic representation comprises a digital twin generated by a digital twin generator, the digital twin generator executed by the one or more processors and comprising:
a set of abstract classes associated with various physical systems and/or components of the various physical systems, an abstract class defining general base characteristics of the various physical systems, their components, and/or implementation of the various physical systems and/or their components in the simulated real world conditions;
the trained parameterized model, the trained parameterized model further configured to:
determine an abstract class and/or classes for the real object based on the user input and/or the characteristics; and
generate code, starting from a determined abstract class and/or classes, and based on the user input and/or the characteristics, to define and customize the digital twin of the real object for simulation in the real world conditions in the virtual world digital environment;
a model-view-controller framework, the model-view-controller framework comprising:
an application programming interface (API) configured to define:
interactions between the digital twin and the simulated real world conditions in the virtual world digital environment;
positions of the digital twin in the virtual world digital environment;
a state of the digital twin and/or the simulated real world conditions in the virtual world digital environment; and/or
movement of the digital twin through the virtual world digital environment;
a user interface configured to generate a multidimensional representation of the digital twin in the virtual world digital environment for a visualization by a user; and
a controller configured to control the interactions, positions, state, and movement of the digital twin in the simulated real world conditions in the virtual world digital environment over time;
wherein the trained parameterized model is configured to generate the code for use by the API, the user interface, and the controller for customizing the digital twin with the simulated real world conditions in the virtual world digital environment according to the user input.

69. The method of claim 61, wherein the trained parameterized model is configured to receive multi modal user inputs.

70. The method of claim 69, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.

71. A method for updating a digital environment based on real world conditions, the method comprising:
receiving, with one or more processors, user and/or sensor input specifying the real world conditions; and
executing, with the one or more processors, a trained parameterized model to:
generate code, based on the user and/or sensor input, to define and customize a digital environment to simulate the real world conditions; and
automatically adjust simulated real world conditions in the digital environment based on additionally received actual data from the real world, wherein automatically adjusting comprises comparing data from the simulated real world conditions in the digital environment to the additionally received actual data from the real world, and adjusting the code for the simulated real world conditions in the digital environment such that data from the simulated real world conditions in the digital environment more closely matches the additionally received actual data from the real world.

72. The method of claim 71, wherein adjusting the code comprises changing a parameter of the simulated real world conditions in the digital environment.

73. The method of claim 71, wherein the trained parameterized model comprises a large language model.

74. The method of claim 71, wherein the trained parameterized model comprises a generative transformer.

75. The method of claim 71, wherein the simulated real world conditions in the digital environment comprise multiple levels of abstraction.

76. The method of claim 75, wherein the multiple levels of abstraction are associated with different time scales, and wherein a time scale is measured in years, months, weeks, days, hours, minutes, seconds, milliseconds, or femtoseconds.

77. The method of claim 71, wherein the simulated real world conditions in the digital environment comprise a physics based model of the simulated real world conditions in the digital environment.

78. The method of claim 71, wherein the trained parameterized model is configured to receive multi modal user inputs.

79. The method of claim 78, wherein the multi modal user inputs comprise at least two different input modality types including two or more of text, image, video, audio, and electromagnetic inputs, and wherein the multi modal using inputs comprising the at least two different input modality types include a first input comprising text, an image, a video, audio input, or an electromagnetic input, and a second input comprising a different one of the text, image, video, audio input, or electromagnetic input.

80. The method of claim 71, wherein the code comprises Python code.
